(19) United States
(12) Patent Application Publication
(10) Pub. No.: US 2026/0223302 A1
(43) Pub. Date: Jul. 30, 2026

(54) MAGNET ASSEMBLY AND ELECTRONIC DEVICE COMPRISING SAME

(71) Applicant: Samsung Electronics Co., Ltd., Suwon-si (KR)

(72) Inventors: Gyuyeong CHO, Suwon-si (KR); Sangil PARK, Suwon-si (KR); Jaedeok LIM, Suwon-si (KR)

(21) Appl. No.: 19/573,681

(22) Filed: Mar. 20, 2026

Related U.S. Application Data
(63) Continuation of application No. PCT/KR2024/014311, filed on Sep. 23, 2024.

(30) Foreign Application Priority Data
Sep. 21, 2023 (KR) 10-2023-0126620
Oct. 18, 2023 (KR) 10-2023-0139564

(51) Int. Cl. H05K 5/02; H01F 7/02

(52) U.S. Cl. CPC H05K 5/0217; H01F 7/02; H05K 5/0247

(57) ABSTRACT

An electronic device includes a housing including a first surface, a second surface, and a first through hole in the side surface, a display disposed on the first surface of the housing, a digitizer disposed in the housing to face the display, a pen accommodating portion extending from the first through hole in a first axis direction and disposed between the digitizer and the second surface of the housing, and a magnet assembly including a plurality of magnetic regions arranged in the first axis direction around the pen accommodating portion, wherein polarities of adjacent magnetic regions among the plurality of magnetic regions are opposite, and wherein a magnetic force of one magnetic region of the adjacent magnetic regions disposed closer to the first through hole than an other magnetic region of the adjacent magnetic regions is equal to or less than a magnetic force of the other magnetic region.

### CROSS-REFERENCE TO RELATED APPLICATION(S)

This application is a continuation application, claiming priority under 35 U.S.C. § 365(c), of an International application No. PCT/KR 2024/014311, filed on Sep. 23, 2024, which is based on and claims the benefit of a Korean patent application number 10-2023-0126620, filed on Sep. 21, 2023, in the Ministry of Intellectual Property (MOIP), and of a Korean patent application number 10-2023-0139564, filed on Oct. 18, 2023, in the Ministry of Intellectual Property (MOIP), the disclosure of each of which is incorporated by reference herein in its entirety.

### BACKGROUND

### 1. Field

The disclosure relates to a magnet assembly and an electronic device including the same.

### 2. Description of Related Art

With the development of information and communication technology and semiconductor technology, various functions are being integrated into a single portable electronic device. For example, the electronic device may implement not only a communication function but also entertainment functions such as games, multimedia functions such as music and video playback, communication and security functions for mobile banking, or functions for schedule management and an electronic wallet. Such electronic devices are being miniaturized to allow a user to conveniently carry the electronic devices.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide a magnet assembly and an electronic device including the same.

Additional aspects will be set forth in part in the description which follows and, in part, will be apparent from the description, or may be learned by practice of the presented embodiments.

In accordance with an aspect of the disclosure, an electronic device is provided. The electronic device includes a housing including a first surface, a second surface facing in a direction opposite to the first surface, a side surface surrounding a space between the first surface and the second surface, and a first through hole in the side surface, a display disposed on the first surface of the housing, a digitizer disposed in the housing to face the display, a pen accommodating portion extending from the first through hole in a first axis direction and disposed between the digitizer and the second surface of the housing, and a magnet assembly including a plurality of magnetic regions arranged in the first axis direction around the pen accommodating portion, wherein polarities of adjacent magnetic regions among the plurality of magnetic regions are opposite, and wherein a magnetic force of one magnetic region of the adjacent magnetic regions disposed closer to the first through hole than an other magnetic region of the adjacent magnetic regions is equal to or less than a magnetic force of the other magnetic region.

In accordance with another aspect of the disclosure, an electronic device is provided. The electronic device includes a housing including a first surface and a second surface facing in a direction opposite to the first surface, a display disposed on the first surface of the housing, a digitizer disposed in the housing to face the display, and a magnet assembly disposed between the digitizer and the second surface of the housing, the magnet assembly including a plurality of magnetic regions arranged in a first axis direction, wherein polarities of adjacent magnetic regions among the plurality of magnetic regions are opposite, and wherein, among two adjacent magnetic regions of the plurality of magnetic regions, a magnetic force of a magnetic region disposed closer to a first through hole of the housing is equal to or less than a magnetic force of an other magnetic region of the two adjacent magnetic regions.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment, according to an embodiment of the disclosure;

FIG. 2 is a front perspective view of an electronic device, according to an embodiment of the disclosure;

FIG. 3 is a rear perspective view of an electronic device, according to an embodiment of the disclosure;

FIG. 4 is a front exploded perspective view of an electronic device, according to an embodiment of the disclosure;

FIG. 5 is a rear exploded perspective view of an electronic device, according to an embodiment of the disclosure;

FIG. 6 is a view for explaining an operation of a digital pen, according to an embodiment of the disclosure;

FIG. 7 is a block diagram illustrating a digital pen, according to an embodiment of the disclosure;

FIG. 8 is a perspective view of an electronic device, according to an embodiment of the disclosure;

FIG. 9A is a side cross-sectional view taken along line A-A of FIG. 8, according to an embodiment of the disclosure;

FIG. 9B is a side cross-sectional view taken along line A-A of FIG. 8, according to an embodiment of the disclosure;

FIG. 10A is a view for explaining a magnetic field generated by the magnet assembly of FIG. 9A according to an embodiment of the disclosure;

FIG. 10B is a view for explaining a magnetic field generated by the magnet assembly of FIG. 9B according to an embodiment of the disclosure;

FIG. 11 is a side cross-sectional view illustrating a magnet assembly of an electronic device, according to an embodiment of the disclosure;

FIG. 12 is a flowchart illustrating a method of manufacturing the magnet assembly of FIG. 11, according to an embodiment of the disclosure;

FIG. 13 is a side cross-sectional view illustrating a magnet assembly of an electronic device, according to an embodiment of the disclosure;

FIG. 14 is a flowchart illustrating a method of manufacturing the magnet assembly of FIG. 13, according to an embodiment of the disclosure;

FIG. 15 is a side cross-sectional view illustrating a magnet assembly of an electronic device, according to an embodiment of the disclosure;

FIGS. 16A and 16B are views illustrating an arrangement of magnetic regions and magnetic field strength of a magnet assembly, according to various embodiments of the disclosure;

FIG. 17 is a view illustrating an arrangement of magnetic regions and magnetic field strength of a magnet assembly, according to an embodiment of the disclosure;

FIG. 18 is a view illustrating an arrangement of magnetic regions and magnetic field strength of a magnet assembly, according to an embodiment of the disclosure;

FIG. 19A is a view for explaining a distribution of magnetic members disposed in an electronic device, according to an embodiment of the disclosure;

FIG. 19B is a plan view illustrating a magnet assembly and a digital pen disposed in an electronic device, according to an embodiment of the disclosure;

FIG. 20 is a plan view illustrating a magnet assembly and a digital pen, according to an embodiment of the disclosure;

FIG. 21 is a view for explaining a magnetic field distribution of a magnet assembly, according to an embodiment of the disclosure;

FIG. 22A is a view for explaining a magnet assembly and a magnetic field distribution, according to an embodiment of the disclosure;

FIG. 22B is a side cross-sectional view of the magnet assembly of FIG. 22A, according to an embodiment of the disclosure;

FIG. 23A is a view for explaining a magnet assembly and a magnetic field distribution, according to an embodiment of the disclosure;

FIG. 23B is a side cross-sectional view of the magnet assembly of FIG. 23A, according to an embodiment of the disclosure; and

FIG. 24 is a view for explaining a demagnetization device of an electronic device and a digital pen, according to an embodiment of the disclosure.

Throughout the drawings, like reference numerals will be understood to refer to like parts, components, and structures.

### DETAILED DESCRITION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

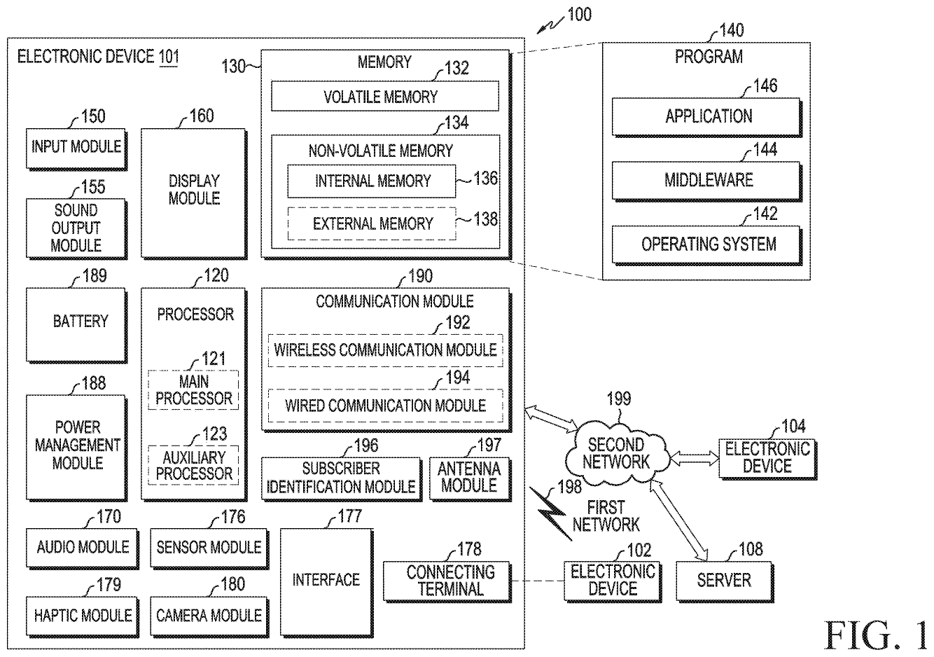

FIG. 1 is a block diagram illustrating an electronic device in a network environment according to an embodiment of the disclosure.

Referring to FIG. 1, the electronic device 101 in the network environment 100 may communicate with an external electronic device 102 via a first network 198 (e.g., a short-range wireless communication network), or an external electronic device 104 or a server 108 via a second network 199 (e.g., a long-range wireless communication network). According to an embodiment, the electronic device 101 may communicate with the external electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In an embodiment, at least one (e.g., the connecting terminal 178) of the components may be omitted from the electronic device 101, or one or more other components may be added in the electronic device 101. In an embodiment, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least portion of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to an embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be configured to use lower power than the main processor 121 or to be specified for a designated function. The auxiliary processor 123 may be implemented as separate from, or as portion of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as portion of another component (e.g., the camera module 180 or the communication module 190) functionally related to the auxiliary processor 123. According to an embodiment, the auxiliary processor 123 (e.g., the neural processing unit) may include a hardware structure specified for artificial intelligence model processing. The artificial intelligence model may be generated via machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. The input module 150 may include, for example, a microphone, a mouse, a keyboard, keys (e.g., buttons), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as portion of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include a touch sensor configured to detect a touch, or a pressure sensor configured to measure the intensity of a force generated by the touch.

The audio module 170 may convert a sound into an electrical signal and vice versa. According to an embodiment, the audio module 170 may obtain the sound via the input module 150, or output the sound via the sound output module 155 or via an external electronic device (e.g., electronic device 102, such as a speaker or a headphone) directly or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the external electronic device 102) directly (e.g., wiredly) or wirelessly. According to an embodiment, the interface 177 may include, for example, a high-definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the external electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or motion) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to an embodiment, the power management module 188 may be implemented as at least portion of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the external electronic device 102, the external electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device 104 via a first network 198 (e.g., a short-range communication network, such as Bluetooth^{TM}, wireless-fidelity (Wi-Fi) direct, or infrared data association (IrDA)) or a second network 199 (e.g., a long-range communication network, such as a legacy cellular network, a 5G network, a next-generation communication network, the Internet, or a computer network (e.g., local area network (LAN) or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a 4G network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the mmWave band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the external electronic device 104), or a network system (e.g., the second network 199). According to an embodiment, the wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device). According to an embodiment, the antenna module 197 may include one antenna including a radiator formed of a conductor or conductive pattern formed on a substrate (e.g., a printed circuit board (PCB)). According to an embodiment, the antenna module 197 may include a plurality of antennas (e.g., an antenna array). In this case, at least one antenna appropriate for a communication scheme used in a communication network, such as the first network 198 or the second network 199, may be selected from the plurality of antennas by, e.g., the communication module 190. The signal or the power may then be transmitted or received between the communication module 190 and the external electronic device via the selected at least one antenna. According to an embodiment, other portions (e.g., radio frequency integrated circuit (RFIC)) than the radiator may be further formed as portion of the antenna module 197.

According to an embodiment, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, instructions or data may be transmitted or received between the electronic device 101 and the external electronic device 104 via the server 108 coupled with the second network 199. The external electronic devices 102 or 104 each may be a device of the same or a different type from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least portion of the function or the service. The one or more external electronic devices receiving the request may perform the at least portion of the function or the service requested, or an additional function or an additional service related to the request, and transfer an outcome of the performing to the electronic device 101. The electronic device 101 may provide the outcome, with or without further processing of the outcome, as at least portion of a reply to the request. To that end, a cloud computing, distributed computing, mobile edge computing (MEC), or client-server computing technology may be used, for example. The electronic device 101 may provide ultra low-latency services using, e.g., distributed computing or mobile edge computing. In an embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or health-care) based on 5G communication technology or IoT-related technology.

In the following detailed description, reference may be made to a length direction, a width direction, and/or a thickness direction of an electronic device. The length direction may be defined as a “Y-axis direction,” the width direction may be defined as an “X-axis direction,” and/or the thickness direction may be defined as a “Z-axis direction.” In an embodiment, with respect to directions toward which components are oriented, negative/positive (−/+) directions may be referred to together with an orthogonal coordinate system illustrated in the drawings. For example, a front surface of the electronic device or a housing may be defined as a surface facing a +Z direction, and a rear surface may be defined as a surface facing a −Z direction. In an embodiment, a side surface of the electronic device or the housing may include a region facing a +X direction, a region facing a +Y direction, a region facing a −X direction, and/or a region facing a −Y direction. In another embodiment, the term “X-axis direction” may have a meaning including both a −X direction and a +X direction. These descriptions are based on the orthogonal coordinate system shown in the drawings for convenience of description, and it should be noted that descriptions of such directions or components do not limit an embodiment disclosed in the disclosure. For example, depending on whether the electronic device is in an unfolded state or a folded state, directions faced by the aforementioned front surface or rear surface may vary, and the aforementioned directions may be interpreted differently depending on a user's holding habit.

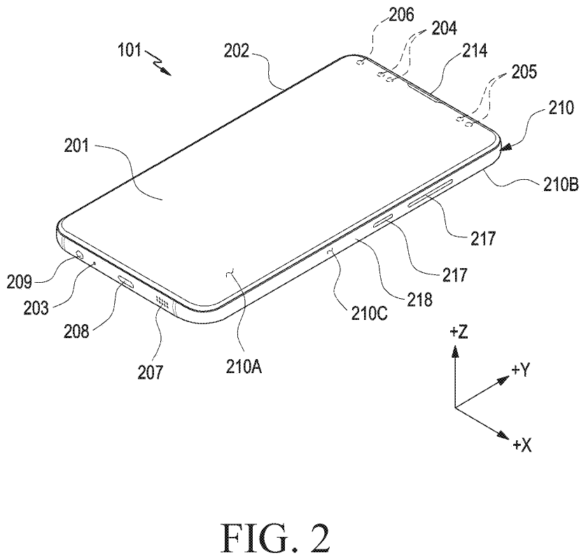

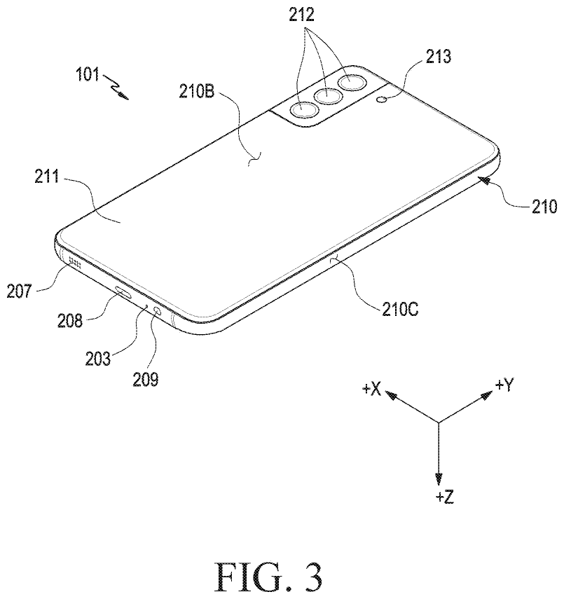

FIG. 2 is a perspective view illustrating a front surface of an electronic device according to an embodiment of the disclosure. FIG. 3 is a perspective view illustrating a rear surface of the electronic device shown in FIG. 2 according to an embodiment of the disclosure. The configuration of the electronic device 101 of FIGS. 2 and 3 may be the same as all or part of the configuration of the electronic device 101 of FIG. 1.

Referring to FIGS. 2 and 3, an electronic device 101 according to an embodiment may include a housing 210 including a first surface (or a front surface) 210A, a second surface (or a rear surface) 210B, and a side surface 210C surrounding a space between the first surface 210A and the second surface 210B. In an embodiment (not shown), the housing 210 may refer to a structure forming a part of the first surface 210A of FIG. 2, the second surface 210B and the side surfaces 210C of FIG. 3. According to an embodiment, the first surface 210A may be formed by a front plate 202 (e.g., a glass plate including various coating layers, or a polymer plate), at least a portion of which is substantially transparent. The second surface 210B may be formed by a substantially opaque rear plate 211. The rear plate 211 may be formed of, for example, coated or colored glass, ceramic, polymer, metal (e.g., aluminum, stainless steel (STS), or magnesium), or a combination of at least two of the above materials. The side surface 210C may be formed by a side structure (or a “side bezel structure”) 218 that is coupled to the front plate 202 and the rear plate 211 and includes metal and/or polymer. In an embodiment, the rear plate 211 and the side structure 218 may be integrally formed and include the same material (e.g., a metallic material such as aluminum).

Although not illustrated, the front plate 202 may include region(s) that are bent toward the rear plate 211 and seamlessly extended at least at a portion of an edge. In an embodiment, the front plate 202 (or the rear plate 211) may include only one of regions that are bent and extended toward the rear plate 211 (or the front plate 202) at one side edge of the first surface 210A. According to an embodiment, the front plate 202 or the rear plate 211 may have a substantially flat plate shape, and in this case, may not include a bent and extended region. When a bent and extended region is included, a thickness of the electronic device 101 at a portion in which the bent and extended region is included may be smaller than a thickness at another portion.

According to an embodiment, the electronic device 101 may include at least one of a display 201, an audio module (not shown) (e.g., the audio module 170 of FIG. 1) including at least one sound hole 203, 207, and 214, a sensor module 204 (e.g., the sensor module 176 of FIG. 1), a camera module 205, 212, and 213 (e.g., the camera module 180 of FIG. 1), a key input device 217 (e.g., the input module 150 of FIG. 1), or connector holes 208 and 209 (e.g., the connection terminal 178 of FIG. 1). In an embodiment, the electronic device 101 may omit at least one of the components (e.g., the key input device 217 or a light-emitting element 206) or may additionally include other components.

According to an embodiment, the display 201 may be visually exposed, for example, through a substantial portion of the front plate 202. In an embodiment, at least a portion of the display 201 may be visually exposed through the front plate 202 forming the first surface 210A or through a portion of the side surface 210C. In an embodiment, an edge of the display 201 may be formed to be substantially the same as an adjacent outer shape of the front plate 202. In an embodiment (not shown), in order to expand an area where the display 201 is visually exposed, a distance between the periphery of the display 201 and the periphery of the front plate 202 may be substantially the same.

In an embodiment (not shown), a recess or an opening may be formed in a portion of a screen display area of the display 201, and at least one of an acoustic hole 214, a sensor module 204, a camera module 205, and a light emitting element 206 aligned with the recess or the opening may be included. In an embodiment (not shown), at least one of an acoustic hole 214, a sensor module 204, a camera module 205, a fingerprint sensor (not shown), and a light emitting element 206 may be included on the rear surface of the screen display area of the display 201. In an embodiment (not shown), the display 201 may be coupled with or disposed adjacent to a touch sensing circuit, a pressure sensor capable of measuring a strength (pressure) of a touch, and/or a digitizer configured to detect a magnetic-field-based stylus pen. In an embodiment, at least a portion of the sensor module 204 and/or at least a portion of a key input device 217 may be disposed on the side surface 210C.

According to an embodiment, an audio module (not shown) may include a microphone hole 203 and acoustic holes 207 and 214. The microphone hole 203 may have a microphone disposed therein to obtain external sound, and in an embodiment, a plurality of microphones may be disposed to detect a direction of sound. According to an embodiment, the acoustic holes 207 and 214 may include an external acoustic hole 207 and a receiver hole 214 for a call. In an embodiment, the acoustic holes 207 and 214 and the microphone hole 203 may be implemented as a single hole, or a speaker may be included in the audio module without the acoustic holes 207 and 214 (e.g., a piezo speaker).

According to an embodiment, a sensor module 204 may generate an electrical signal or a data value corresponding to an internal operating state of the electronic device 101 or an external environmental state. The sensor module 204 may include, for example, a first sensor module 204 (e.g., a proximity sensor) disposed on a first surface 210A of the housing 210 and/or a second sensor module (not shown) (e.g., a fingerprint sensor). According to an embodiment, an additional sensor module disposed on a second surface 210B of the housing 210 may be provided. The fingerprint sensor (not shown) may be disposed not only on the first surface 210A of the housing 210 (e.g., the display 201) but also on the second surface 210B or the side surface 210C. The electronic device 101 may further include, for example, at least one of a gesture sensor, a gyro sensor, a barometric pressure sensor, a magnetic sensor, an acceleration sensor, a grip sensor, a color sensor, an infrared (IR) sensor, a biometric sensor, a temperature sensor, a humidity sensor, or an illuminance sensor.

According to an embodiment, camera modules 205, 212, and 213 may include a first camera module 205 facing a first surface 210A of the electronic device 101, and a second camera module 212 and/or a flash 213 facing a second surface 210B. For example, the first camera module 205 and/or the second camera module 212 may include one or a plurality of lenses, an image sensor, and/or an image signal processor. According to an embodiment, some camera modules 205 and/or some sensor modules (e.g., the sensor module 204) among the camera modules 205 and 212 may be disposed to be exposed to the outside through at least a portion of the display 201. According to an embodiment, the first camera module 205 may include a punch hole camera disposed inside a hole or a recess formed on the rear surface of the display 201. For example, the first camera module 205 may receive at least a portion of light incident from a first surface 210A (or a front surface) of the electronic device 101 through the display 201 from inside the electronic device 101.

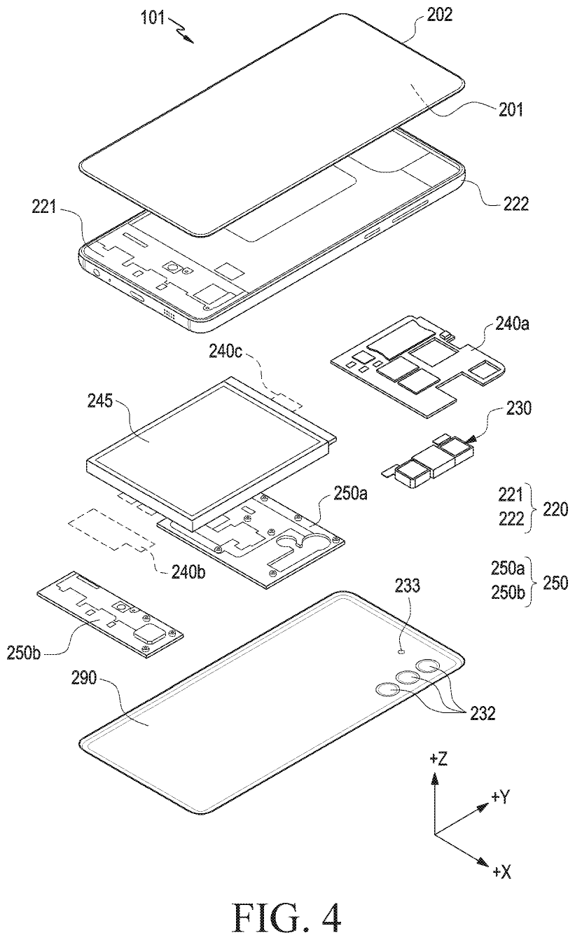

According to an embodiment, the second camera module 212 may be disposed inside the housing 210 such that a lens is exposed toward a second surface 210B (or a rear surface) of the electronic device 101. For example, the camera module 212 may be electrically connected to a printed circuit board (e.g., the printed circuit board 240a of FIG. 4). For example, the flash 213 may include a light emitting diode or a xenon lamp. In an embodiment, one or more lenses (an infrared camera, a wide-angle lens, and a telephoto lens) and image sensors may be disposed on one surface of the electronic device 101. In an embodiment, the flash 213 may emit infrared light. For example, infrared light emitted from the flash 213 and reflected by a subject may be received through a sensor module (not shown) disposed on the second surface 210B of the housing 210. The electronic device 101 or a processor (e.g., the processor 180 of FIG. 1) may detect depth information of the subject based on a time point at which the infrared light is received by the sensor module.

According to an embodiment, a key input device 217 may be disposed on the side surface 210C of the housing 210. In an embodiment, the electronic device 101 may not include some or all of the above-described key input devices 217, and the key input devices 217 that are not included in the electronic device may be implemented in another form, such as soft keys, on the display 201. In an embodiment, the key input device may include a sensor module disposed on the second surface 210B of the housing 210.

According to an embodiment, a light emitting element 206 may be disposed, for example, on a first surface 210A of the housing 210. The light emitting element 206 may provide, for example, state information of the electronic device 101 in the form of light. In an embodiment, the light emitting element 206 may provide, for example, a light source interworking with an operation of the camera module 205. The light emitting element 206 may include, for example, an LED, an IR LED, and a xenon lamp.

According to an embodiment, connector holes 208 and 209 may include a first connector hole 208 configured to accommodate a connector (e.g., a USB connector) for transmitting and/or receiving power and/or data to and from an external electronic device, and/or a second connector hole 209 (e.g., an earphone jack) configured to accommodate a connector for transmitting and/or receiving an audio signal to and from an external electronic device.

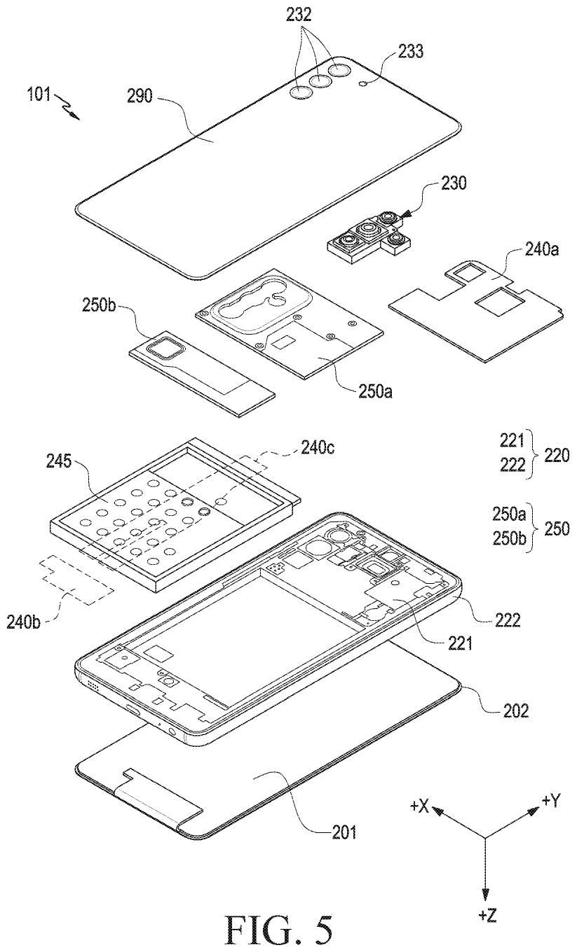

FIG. 4 is an exploded perspective view of a front surface of an electronic device according to an embodiment of the disclosure. FIG. 5 is an exploded perspective view of a rear surface of an electronic device according to an embodiment of the disclosure.

Referring to FIGS. 4 and 5, an electronic device 101 (e.g., the electronic device 101 of FIG. 1 and/or the electronic device 101 of FIG. 2 or FIG. 3) may include a display 201 (e.g., the display 201 of FIG. 2), a front plate 202 (e.g., the front plate 202 of FIG. 2), a support structure 221 (e.g., a bracket), a side bezel structure 222 (or a side bezel structure), a camera module 230 (e.g., the camera module 180 of FIG. 1), at least one printed circuit board (or a board assembly) 240a and 240b, a battery 245 (e.g., the battery 189 of FIG. 1), a rear case 250, an antenna (not shown) (e.g., the antenna module 197 of FIG. 1), and/or a rear plate 290 (e.g., the rear plate 211 of FIG. 3). According to an embodiment, when a plurality of printed circuit boards 240a and 240b are included, the electronic device 101 may electrically connect different printed circuit boards by including at least one flexible printed circuit board 240c. For example, the printed circuit boards 240a and 240b may include a first circuit board 240a disposed above the battery 245 (e.g., in a +Y-axis direction) and a second circuit board 240b disposed below the battery 245 (e.g., in a −Y-axis direction), and the flexible printed circuit board 240c may electrically connect the first circuit board 240a and the second circuit board 240b.

According to an embodiment, the electronic device 101 may omit at least one of the components (e.g., the support structure 221, the rear case 250, or the flexible printed circuit board 240c) or may additionally include other components. At least one of the components of the electronic device 101 may be the same as or similar to at least one of the components of the electronic device 101 of FIG. 2 or FIG. 3, and redundant descriptions thereof will be omitted below.

In an embodiment, at least a portion of the support structure 221 may be provided in a flat plate shape. In an embodiment, the support structure 221 may be disposed inside the electronic device 101 to be connected to the side bezel structure 222 or may be integrally formed with the side bezel structure 222. For example, the support structure 221 may be formed of a conductive material and/or a non-conductive material (e.g., a polymer). When the support structure 221 includes at least partially a conductive material such as metal, the side bezel structure 222 or a portion of the support structure 221 may function as an antenna. The support structure 221 may include two surfaces facing opposite directions. The display 201 may be disposed on one of the two surfaces of the support structure 221, and printed circuit boards 240a and 240b may be disposed on the other surface.

According to an embodiment, the support structure 221 and the side bezel structure 222 may be combined and referred to as a front case or a housing 220. According to an embodiment, the housing 220 may be generally understood as a structure for accommodating, protecting, or arranging electrical/electronic components such as printed circuit boards 240a and 240b or a battery 245. In an embodiment, the housing 220 may be understood to include structures that are visually or tactilely recognizable by a user from the exterior of the electronic device 101, for example, the side bezel structure 222, the front plate 202, and/or the rear plate 290. In an embodiment, a front surface or a rear surface of the housing 220 may refer to the first surface 210A of FIG. 2 or the second surface 210B of FIG. 3. In an embodiment, the support structure 221 may be disposed between the front plate 202 (e.g., the first surface 210A of FIG. 2) and the rear plate 290 (e.g., the second surface 210B of FIG. 3), and may function as a structure for arranging electrical/electronic components such as the printed circuit boards 240a and 240b or the camera module 230. In the following detailed description, the camera module 230 of the electronic device 101 may be exemplarily described as including a configuration for receiving light incident through the second surface 210B of the electronic device 101; however, the electronic device 101 may further include a camera module (e.g., the camera module 205 of FIG. 2) and/or a sensor module (e.g., the sensor module 204 of FIG. 2) disposed to be exposed to the outside through at least a portion of the display 201.

According to an embodiment, the camera module 230 may include at least one camera module, for example, at least one of a plurality of camera modules illustrated in FIGS. 4 and 5. In an embodiment, the camera module 230 may be disposed on a portion of the support structure 221 at a position adjacent to the printed circuit boards 240a and 240b. In an embodiment, the camera module 230 may be at least partially surrounded by the rear case 250 (e.g., an upper rear case 250a). According to an embodiment, the camera module 230 may receive at least a portion of light incident through an optical hole or cover window(s) 232 and 233 disposed on a rear surface of the electronic device 101 (e.g., the second surface 210B of FIG. 3) from inside the electronic device 101. According to an embodiment, the camera module 230 may be generally aligned with any one of the cover windows 232 and 233.

According to an embodiment, various electrical/electronic components may be disposed on the printed circuit boards 240a and 240b, such as circuit devices implemented in the form of integrated circuit chips (e.g., a processor), a communication module (e.g., the communication module 190 of FIG. 1), a power management module (e.g., the power management module 188), memory (e.g., the memory 130 of FIG. 1), an interface (e.g., the interface 177 of FIG. 1), or other electrical/electronic components. The processor (e.g., the processor 120 of FIG. 1) may include one or more of a central processing unit, an application processor, a graphics processing unit, an image signal processor, a sensor hub processor, or a communication processor. The memory may include, for example, a volatile memory or a non-volatile memory. The interface may include, for example, an HDMI, a USB interface, an SD card interface, and/or an audio interface. The interface may, for example, electrically or physically connect the electronic device 101 to an external electronic device, and may include a USB connector, an SD card/MMC connector, or an audio connector. According to an embodiment, the printed circuit boards 240a and 240b may be provided with an electromagnetic shielding environment by the rear case 250.

According to an embodiment, the battery 245 may be a device for supplying power to at least one component of the electronic device 101, and may include, for example, a non-rechargeable primary battery, a rechargeable secondary battery, or a fuel cell. At least a portion of the battery 245 may be disposed, for example, substantially on the same plane as the printed circuit boards 240a and 240b. The battery 245 may be integrally disposed inside the electronic device 101, or may be detachably disposed with respect to the electronic device 101.

According to an embodiment, the rear case 250 may include an upper rear case 250a and a lower rear case 250b. In an embodiment, the upper rear case 250a may be disposed to surround the printed circuit boards 240a and 240b (e.g., a first circuit board 240a) together with a portion of the support structure 221. For example, the upper rear case 250a may be disposed to face the support structure 221 with the first circuit board 240a interposed therebetween.

In an embodiment, the lower rear case 250b may be used as a structure in which various electrical/electronic components, including interfaces (e.g., a USB connector, an SD card/MMC connector, or an audio connector), may be disposed. According to an embodiment, electrical/electronic components such as interfaces (e.g., a USB connector, an SD card/MMC connector, or an audio connector) may be disposed on an additional printed circuit board (not shown). In this case, the lower rear case 250b may be disposed to surround the additional printed circuit board (not shown) together with another portion of the support structure 221. For example, an interface disposed on the additional printed circuit board (not shown) or on the lower rear case 250b may be disposed to correspond to the acoustic hole 207 or the connector holes 208 and 209 of FIG. 2.

According to an embodiment, an antenna (not shown) may include, for example, a conductive pattern formed on a surface of the rear case 250 through a laser direct structuring (LDS) process. In an embodiment, the antenna may include a printed circuit pattern formed on a surface of a thin film, and the antenna in the form of the thin film may be disposed between the rear plate 290 and the battery 245. The antenna may include, for example, a near-field communication (NFC) antenna, a wireless charging antenna, and/or a magnetic secure transmission (MST) antenna. The antenna may, for example, perform near-field communication with an external device or wirelessly transmit and/or receive power required for charging. In an embodiment, another antenna structure may be formed by a portion of the support structure 221 and/or the side bezel structure 222, or a combination thereof.

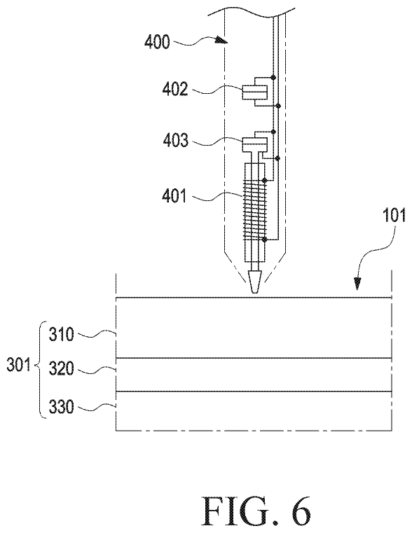

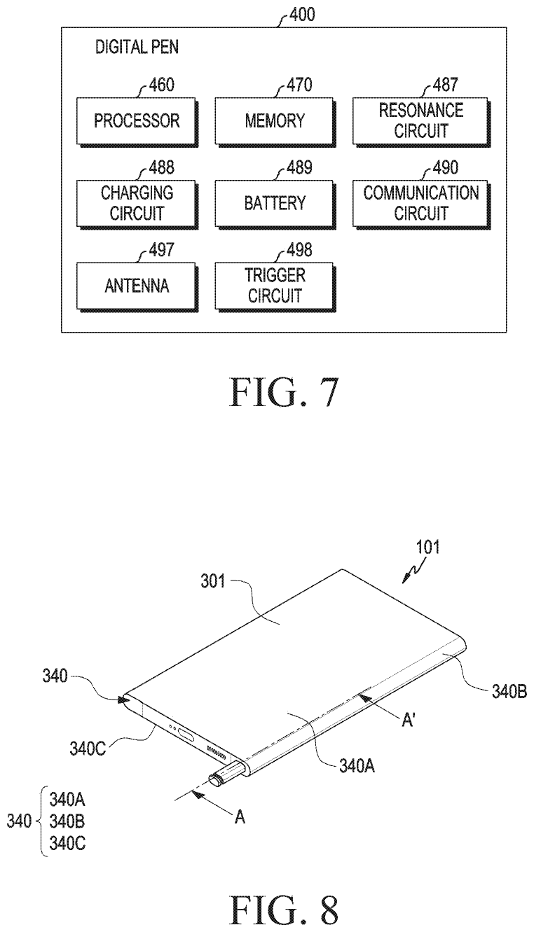

FIG. 6 is a diagram for explaining an operation of a digital pen according to an embodiment of the disclosure. FIG. 7 is a block diagram illustrating a digital pen according to an embodiment of the disclosure.

Referring to FIG. 6, an electronic device 101 may include a display 310, a digitizer 320, and a metal sheet 330. Configurations of the electronic device 101 and the display 310 of FIG. 6 may be the same as or similar to all or part of configurations of the electronic device 101 and the display 201 or 220 of FIGS. 2 to 5.

According to an embodiment, the digitizer 320 may be a panel for detecting an input of a digital pen 400 (e.g., an electromagnetic induction body). The digitizer 320 may be referred to as an electromagnetic induction panel. The digital pen 400 may provide an input to the electronic device 101 using an electro-magnetic resonance (EMR) scheme, an active electrical stylus (AES) scheme, or an electric coupled resonance (ECR) scheme. The digital pen 400 may be referred to as a stylus. For example, the digitizer 320 may include a circuit board (e.g., a printed circuit board or a flexible printed circuit board) and a plurality of coils located in the circuit board. The plurality of coils of the digitizer 320 may generate a magnetic field. The digital pen 400 may resonate based on the magnetic field generated from the digitizer, and a magnetic field may be formed in a coil of the digital pen 400 by the resonance. Due to the magnetic field formed from the digital pen 400, currents may be output from the coils of the digitizer 320. The electronic device 101 may identify (or detect) a position of the digital pen 400 based on magnitudes of currents per channel (e.g., converted digital values) output from the plurality of coils of the digitizer 320.

According to an embodiment, the digitizer 320 may include a pattern layer in which a transmission pattern is formed and a pattern layer in which a reception pattern is formed. The transmission pattern layer and the reception pattern layer may be stacked with each other to generate or detect an electromagnetic field. The electronic device 101 may detect a magnetic field generated from the digital pen 400 through an EMR scheme by using the digitizer 320, and may detect various motions such as approach, click, or drag of the digital pen 400. According to an embodiment, the digitizer 320 may include coils capable of generating a magnetic field based on movement of the digital pen 400. For example, the digitizer 320 may include a coil facing the display 310 and a coil facing an absorber layer of a metal sheet (e.g., the metal sheet 300 of FIG. 6). According to an embodiment, the digitizer 320 may be referred to as a part of the display 310. For example, the display 310 and the digitizer 320 may be provided as a single modular component (e.g., a display assembly).

According to an embodiment, the metal sheet 330 may provide uniform inductance. For example, the metal sheet 330 may include a metal (e.g., copper) and may reduce cancellation interference caused by eddy currents. For example, the metal sheet 330 may reduce eddy currents generated in the digitizer 320 by allowing at least a portion of a magnetic field passing through the digitizer 320 to flow within the metal sheet 330. For example, the metal sheet 330 may support the display 310 and/or the digitizer 320. For example, the metal sheet 330 may also be referred to as a support sheet or a support plate.

According to an embodiment, the metal sheet 330 may include an absorber layer for improving sensitivity for detecting an input (e.g., proximity) of the digital pen 400. For example, the absorber layer may be positioned below the digitizer 320 (in a-Z-axis direction). For example, the absorber layer may increase inductance of a coil 401 of the digital pen 400. For example, the absorber layer may have a specified permeability and/or thickness in order to increase the inductance of the coil 401. According to an embodiment, the absorber layer may reduce electromagnetic interference of the digitizer 320. For example, the absorber layer may include magnetic metal powder. For example, the absorber layer may be referred to as a layer of magnetic metal powder applied below the digitizer 320. The absorber layer may reduce a magnitude of a magnetic field, other than a signal input from the digital pen, transmitted to the digitizer 320 from electronic components located in a housing (e.g., the housing 201 of FIG. 4). As the magnetic field of electronic components located inside the electronic device 101 and transmitted to the digitizer 320 is reduced, noise of the digitizer 320 may be reduced. According to an embodiment, the absorber layer may be referred to as a high-frequency absorber layer.

According to an embodiment, the digital pen 400 may respond to a magnetic field generated by the digitizer 320. For example, the digital pen 400 may include a coil 401 configured to resonate based on the magnetic field generated by the digitizer 320. The digital pen 400 may generate a magnetic field by using resonance of the coil 401. The digitizer 320 may output a current based on the magnetic field generated by the digital pen 400. For example, the coil 401 may be in a form in which a wire is wound around a ferrite material.

According to an embodiment, the digital pen 400 may store power by using a capacitor. For example, the digital pen 400 may include at least one variable capacitor 402 and at least one fixed capacitor 403.

According to an embodiment, memory (e.g., the memory 130 of FIG. 1) of the electronic device 101 may store a calibration value for an operation of the digital pen 400 in a state without interference. A processor (e.g., the processor 120 of FIG. 1) of the electronic device 101 may determine an input of the digital pen 400 by using the calibration value stored in the memory 130. However, when magnetic interference caused by an external magnetic field occurs in the digital pen 400, accuracy of position determination of the digital pen 400 by the processor 120 of the electronic device 101 may be reduced. In the disclosure, magnetic interference occurring in the digital pen 400 may be defined as a phenomenon in which a change occurs in a resonance frequency, which is defined as, as the inductance of the coil 401 is changed by an external magnetic field outside the digital pen 400, thereby causing malfunction of the digital pen 400. Here, the external magnetic field to which the digital pen 400 is exposed may refer to a magnetic field generated from surrounding magnets, such as a magnet present in the electronic device 101.

For example, an inductance value of the coil 401 of the digital pen 400 may be determined depending on a shape in which the coil 401 is wound around a ferrite material and/or permeability of surrounding materials (e.g., ferrite and the metal sheet 330). For example, when inductance is increased due to magnetic interference, capacitance may be detected as being increased, thereby causing a malfunction in which an input is generated in the digitizer 320 even without clicking or writing with the digital pen 400. Conversely, when inductance is decreased due to magnetic interference, capacitance may be detected as being decreased, thereby causing a malfunction in which an input is not generated in the digitizer 320 even when writing with the digital pen 400. For example, an error occurring in the coil 401 of the digital pen 400 may be perceptible to a user when the error exceeds approximately 0.2 μH. For example, the processor 120 of the electronic device 101 may correct a deviation of approximately 0.2 μH to approximately 1 μH by using calibration values stored in memory (e.g., the memory 130 of FIG. 1).

For example, the coil 401 of the digital pen 400 (e.g., ferrite of the coil 401) may be magnetized while approaching and then moving away from a surrounding magnet. For example, when the coil 401, in a magnetized state, again approaches a surrounding magnet, magnetic interference caused by magnetization of the coil 401 and a corresponding malfunction of the digital pen 400 may be intensified. For example, when the coil 401 is exposed to an external magnetic field having a polarity the same as a magnetized polarity of the coil 401 (e.g., an N pole or an S pole), magnetic interference may be intensified. When a magnetic field of a surrounding magnet is in the same direction as the magnetized polarity of the coil 401, magnetic interference may further increase.

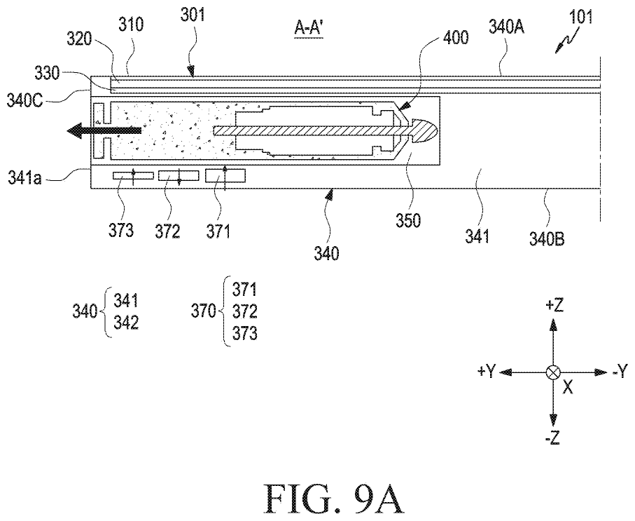

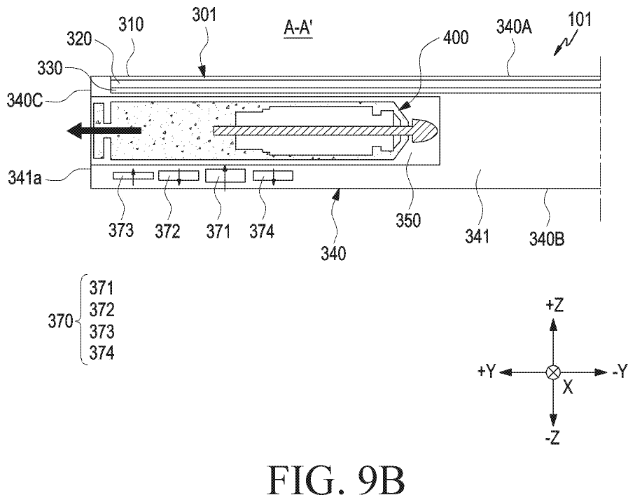

For example, the coil 401 may be demagnetized by alternately applying magnetic fields in a +direction and a −direction with gradually decreasing intensity to the magnetized coil 401 (e.g., ferrite of the coil 401). Specifically, for example, a magnetic field magnetizing the coil 401 to −9 may be applied to the coil 401 magnetized with an intensity of +10, then a magnetic field magnetizing the coil 401 to +8 may be applied, and then a magnetic field magnetizing the coil 401 to −7 may be applied, such that magnetic fields in opposite directions are alternately applied, thereby demagnetizing the coil 401 so that residual magnetism approaches zero. As will be described below, according to an embodiment of the disclosure, the electronic device 101 may include a magnet assembly (e.g., the magnet assembly 370 of FIGS. 9A and 9B) for demagnetizing residual magnetization of the digital pen 400.

FIG. 7 is a block diagram illustrating a digital pen according to an embodiment of the disclosure. Referring to FIG. 7, the digital pen 400 may include a processor 460, memory 470, a resonance circuit 487, a charging circuit 488, a battery 489, a communication circuit 490, an antenna 497, and/or a trigger circuit 498. In some embodiments, the processor 460 of the digital pen 400, at least a portion of the resonance circuit 487, and/or at least a portion of the communication circuit 490 may be configured on a printed circuit board or implemented in the form of a chip. The processor 460, the resonance circuit 487, and/or the communication circuit 490 may be electrically connected to the memory 470, the charging circuit 488, the battery 489, the antenna 497, or the trigger circuit 498. According to an embodiment, the digital pen 400 may be configured with only the resonance circuit 487 and a button.

The processor 460 may include a customized hardware module or a generic processor configured to execute software (e.g., an application program). The processor may include hardware components (functions) and/or software components (programs) including at least one of various sensors provided in the digital pen 400, a data measurement module, an input/output interface, a module for managing a state or an environment of the digital pen 400, or a communication module. The processor 460 may include, for example, one or more combinations of hardware, software, or firmware. According to an embodiment, the processor 460 may receive a proximity signal corresponding to an electromagnetic field signal generated from a digitizer 320 included in a display module (e.g., the display module 160 of FIG. 1) of an electronic device (e.g., the electronic device 101 of FIGS. 1 to 6) through the resonance circuit 487. When the proximity signal is identified, the processor 460 may control the resonance circuit 487 to transmit an electro-magnetic resonance (EMR) input signal to the electronic device 101.

The memory 470 may store information related to operation of the digital pen 400. For example, the information may include information for communication with the electronic device 101 and frequency information related to an input operation of the digital pen 400.

The resonance circuit 487 may include at least one of a coil, an inductor, or a capacitor. The resonance circuit 487 may be used for generating a signal including a resonance frequency by the digital pen 400. For example, for generating the signal, the digital pen 400 may use at least one of an electro-magnetic resonance (EMR) scheme, an active electrostatic (AES) scheme, or an electrically coupled resonance (ECR) scheme. When the digital pen 400 transmits a signal according to the EMR scheme, the digital pen 400 may generate a signal including a resonance frequency based on an electromagnetic field generated from an inductive panel of the electronic device 101. When the digital pen 400 transmits a signal according to the AES scheme, the digital pen 400 may generate a signal by using capacitive coupling with the electronic device 101. When the digital pen 400 transmits a signal according to the ECR scheme, the digital pen 400 may generate a signal including a resonance frequency based on an electric field generated from a capacitive device of the electronic device 101. According to an embodiment, the resonance circuit 487 may be used to change an intensity or a frequency of an electromagnetic field according to a user's operation state. For example, the resonance circuit 487 may provide frequencies for recognizing a hovering input, a drawing input, a button input, or an erasing input.

The charging circuit 488 may, when connected to the resonance circuit 487 based on a switching circuit, rectify a resonance signal generated from the resonance circuit 487 into a direct current (DC) signal and provide the DC signal to the battery 489. According to an embodiment, the digital pen 400 may determine whether the digital pen 400 is inserted into a protective cover (e.g., the protective cover 300 of FIG. 5) by using a voltage level of the DC signal detected by the charging circuit 488.

The battery 489 may be configured to store power required for operation of the digital pen 400. The battery may include, for example, a lithium-ion battery or a capacitor, and may be rechargeable or replaceable. According to an embodiment, the battery 489 may be charged by using power (e.g., a DC signal (DC power)) provided from the charging circuit 488.

The communication circuit 490 may be configured to perform a wireless communication function between the digital pen 400 and a communication module (e.g., the communication module 190 of FIG. 1) of an electronic device (e.g., the electronic device 101 of FIG. 1). According to an embodiment, the communication circuit 490 may transmit state information and input information of the digital pen 400 to the electronic device 101 by using a short-range communication scheme. For example, the communication circuit 490 may transmit, to the electronic device 101, direction information of the digital pen 400 (e.g., motion sensor data) obtained through the trigger circuit 498, voice information received through a microphone, or remaining battery level information of the battery 489. As an example, the short-range communication scheme may include at least one of Bluetooth, Bluetooth Low Energy (BLE), or wireless LAN.

The antenna 497 may be used to transmit a signal or power to the outside (e.g., the electronic device 101) or receive a signal or power from the outside. According to an embodiment, the digital pen 400 may include a plurality of antennas 497, and may select at least one antenna 497 suitable for a communication scheme among the plurality of antennas 497. Through the selected at least one antenna 497, the communication circuit 490 may exchange a signal or power with an external electronic device.

The trigger circuit 498 may include at least one button or a sensor circuit. According to an embodiment, the processor 460 may identify an input scheme (e.g., touch or press) or a type (e.g., an EMR button or a BLE button) of a button of the digital pen 400. According to an embodiment, the sensor circuit may generate an electrical signal or a data value corresponding to an internal operating state of the digital pen 400 or an external environmental state. For example, the sensor circuit may include at least one of a motion sensor, a battery level detection sensor, a pressure sensor, a light sensor, a temperature sensor, a geomagnetic sensor, or a biometric sensor. According to an embodiment, the trigger circuit 498 may transmit a trigger signal to the electronic device 101 by using a button input signal or a signal from a sensor. Configurations of the resonance circuit 487 and the battery 489 of FIG. 7 may be the same as or similar to all or part of configurations of the coil 401 and the capacitors 402 and 403 of FIG. 6.

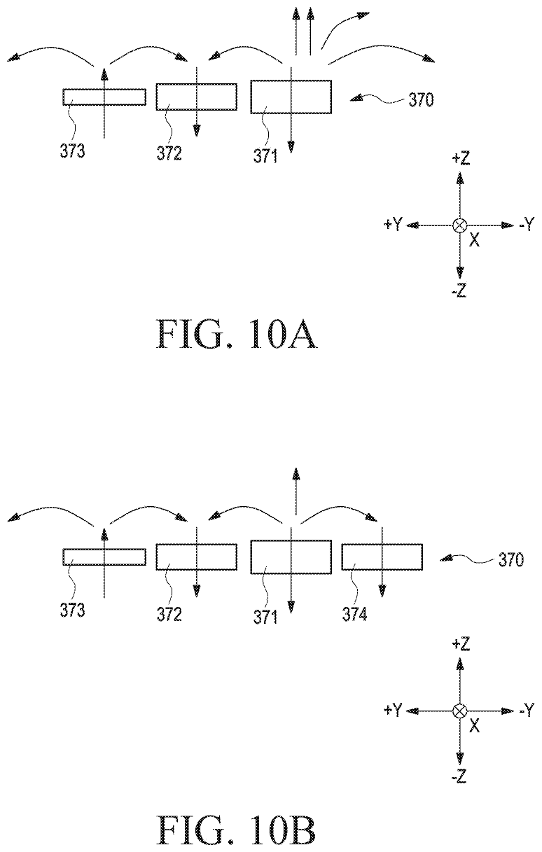

FIG. 8 is a perspective view of an electronic device according to an embodiment of the disclosure. FIG. 9A is a side cross-sectional view taken along line A-A of FIG. 8 according to an embodiment of the disclosure. FIG. 9B is a side cross-sectional view taken along line A-A of FIG. 8 according to an embodiment of the disclosure. FIG. 10A is a diagram for explaining a magnetic field generated by a magnet assembly of FIG. 9A according to an embodiment of the disclosure. FIG. 10B is a diagram for explaining a magnetic field generated by a magnet assembly of FIG. 9B according to an embodiment of the disclosure.

All or part of a configuration of the electronic device 101 of FIG. 8 may be the same as or similar to a configuration of the electronic device 101 of FIGS. 1 to 6.

Referring to FIGS. 8, 9A, and 9B, in an embodiment, the electronic device 101 may include a housing 340 (e.g., the housing 210 of FIGS. 2 and 3, the housing 220 of FIGS. 4 and 5, and/or the housing 330 of FIG. 6), a display 310 (e.g., the display 201 of FIGS. 2 to 5), a digitizer 320 (e.g., the digitizer 320 of FIG. 6), a metal sheet 330 (e.g., the metal sheet 330 of FIG. 6), a pen accommodating portion 350, and a magnet assembly 370. The digital pen 400 (e.g., the digital pen 400 of FIG. 6) may be magnetized by surrounding magnets during use. As will be described below, according to an embodiment of the disclosure, during a user operation of accommodating or removing the magnetized digital pen 400 with respect to the pen accommodating portion 350, the digital pen 400 may be demagnetized by being exposed to a magnetic field (or an attenuated magnetic field) of the magnet assembly 370. By the demagnetization function of the digital pen 400 by the magnet assembly 370, an input malfunction of the digital pen 400 caused by magnetic interference of the magnetized digital pen 400 may be suppressed.

According to an embodiment, a housing 340 of the electronic device 101 may include a first surface 340A (e.g., the first surface 210A of FIG. 2), a second surface 340B (e.g., the second surface 210B of FIG. 3) facing a direction opposite to the first surface 340A, and a side surface 340C surrounding a space between the first surface 340A and the second surface 340B. According to an embodiment, the housing 340 may include a front plate that is at least partially substantially transparent (e.g., the front plate 202 of FIG. 2) (e.g., a glass plate including various coating layers, or a polymer plate), and the first surface 340A may be formed by the front plate. According to an embodiment, the housing 340 may include a rear plate (e.g., the rear plate 211 of FIG. 3), and the second surface 340B may be formed by the rear plate. According to an embodiment, the housing 340 may include a support structure 341 disposed inside the electronic device 101 and configured to support electrical/electronic components (e.g., printed circuit boards) of the electronic device 101.

According to an embodiment, a side structure 342 may be disposed on a side portion of the housing 340. According to an embodiment, the housing 340 may include a first through hole 341a formed in a side surface 340C. The first through hole 341a may be connected to the pen accommodating portion 350 of the electronic device 101. In FIG. 8, the first through hole 341a is illustrated as being located at an upper portion of the electronic device 101 (e.g., a side surface 340C in a +Y-axis direction); however, the position of the first through hole 341a may vary in the disclosure. For example, the first through hole 341a may be located at left or right end portions (e.g., side surfaces 340C in an X-axis direction) of the electronic device 101.

According to an embodiment, the pen accommodating portion 350 of the electronic device 101 may be formed to accommodate a digital pen 400 external to the electronic device 101. For example, the digital pen 400 may be accommodated in or removed from the pen accommodating portion 350 in a direction indicated by an arrow of FIG. 9A. According to an embodiment, the pen accommodating portion 350 may be disposed between the digitizer 320 (or the metal sheet 330) and a second surface 340B of the housing 340. According to an embodiment, the pen accommodating portion 350 may be formed in a support structure 341 of the housing 340. The pen accommodating portion 350 may be a space extending from a first through hole 341a in a first axis direction (e.g., a Y-axis direction) in the support structure 341. In the disclosure, an arrangement and a shape of the pen accommodating portion 350 may vary. For example, the first through hole 341a may be located at left or right end portions (e.g., side surfaces 340C in an X-axis direction) of the electronic device 101, and the pen accommodating portion 350 may extend in a lateral direction (e.g., an X-axis direction).

According to an embodiment, a magnet assembly 370 of the electronic device 101 may include a plurality of magnetic regions 371, 372, and 373 arranged or aligned around the pen accommodating portion in the first axis direction (e.g., a Y-axis direction). According to an embodiment, polarities (e.g., an N pole or an S pole) of adjacent magnetic regions 371, 372, and 373 among the magnetic regions 371, 372, and 373 of the magnet assembly 370 may be opposite to each other. Among two adjacent magnetic regions 371, 372, and 373, a magnetic force of a magnetic region 371 or 372 disposed closer to the first through hole 341a of the housing 340 may be equal to or less than a magnetic force of the other magnetic region 372 or 373.

According to an embodiment, the magnetic regions 371, 372, and 373 of the magnet assembly 370 may be disposed between the pen accommodating portion 350 and the second surface 340B of the housing 340. For example, as the magnetic regions 371, 372, and 373 of the magnet assembly 370 are disposed farther from the digitizer 320, magnetic-field interference with respect to the digitizer 320 caused by the magnetic regions 371, 372, and 373 may be reduced or prevented.

Referring to FIGS. 9A and 9B, according to an embodiment, magnetic regions 371, 372, and 373 of the magnet assembly 370 may include a first magnetic region 371 disposed furthest from the first through hole 341a of the housing 340, a third magnetic region 373, and a second magnetic region 372 disposed between the first magnetic region 371 and the third magnetic region 373. According to an embodiment, a magnetic force or a strength of a magnetic field may gradually increase from the third magnetic region 373 to the second magnetic region 372 and to the first magnetic region 371. According to an embodiment, magnetization of the first magnetic region 371 may be opposite to magnetization of the second magnetic region 372, and magnetization of the second magnetic region 372 may be opposite to magnetization of the third magnetic region 373. For example, the magnetic regions 371, 372, and 373 may be disposed spaced apart from each other. For example, a spacing distance between the magnetic regions 371, 372, and 373 may be constant or variable. In the disclosure, a number, a shape, and an arrangement of the magnetic regions 371, 372, and 373 are not limited and may vary.

According to an embodiment, a digital pen 400 (e.g., the digital pen 400 of FIG. 6) may be magnetized by surrounding magnets, and the digital pen 400 may be demagnetized by the magnet assembly 370 when the digital pen 400 is accommodated in or removed from the pen accommodating portion 350 in a magnetized state. According to an embodiment, the digital pen 400 may be demagnetized by being exposed to a magnetic field (or an attenuated magnetic field) of the magnet assembly 370 while the digital pen 400 moves within the pen accommodating portion 350. The attenuated magnetic field of the magnet assembly 370 may alternate in a +direction and a −direction, and a magnitude of the attenuated magnetic field may gradually increase as a distance from the first through hole 341a of the housing 340 increases. Accordingly, residual magnetism of the coil 401 may approach zero, and the coil 401 may be demagnetized.

Referring to FIG. 9B, according to an embodiment, the magnet assembly 370 may further include an additional magnetic region 374 (or a fourth magnetic region) adjacent to the first magnetic region 371. The additional magnetic region 374 may at least partially face the first magnetic region 371. According to an embodiment, magnetization of the additional magnetic region 374 may be opposite to magnetization of the first magnetic region 371. According to an embodiment, a magnetic force (or a strength of a magnetic field) of the additional magnetic region 374 may be less than a magnetic force (or a strength of a magnetic field) of the first magnetic region 371. For example, the additional magnetic region 374 may be aligned or overlapped with respect to the first magnetic region 371 based on a first axis direction (e.g., a Y-axis direction).

FIGS. 10A and 10B are schematic diagrams for explaining a change in a magnetic field of the first magnetic region 371 depending on whether the additional magnetic region 374 is provided. Referring to FIG. 10A, the first magnetic region 371 may have the largest magnetic force (or magnetic field strength) among the magnetic regions 371, 372, and 373, and accordingly, an influence of magnetic-field interference on surrounding electrical/electronic components such as the digitizer 320 may be relatively greater than that of the second magnetic region 372 and the third magnetic region 373. For example, the digitizer 320 may be disposed above the magnetic regions 371, 372, and 373 (in a +Z-axis direction) with reference to FIGS. 10A and 10B, and a magnetic field of the first magnetic region 371 may act toward the digitizer 320. Referring to FIG. 10B, a portion of the magnetic field of the first magnetic region 371 may act toward the additional magnetic region 374, thereby suppressing or reducing an influence of the magnetic field of the first magnetic region 371 acting toward the digitizer 320. Referring to FIGS. 10A and 10B, according to an embodiment, when the magnet assembly 370 includes the additional magnetic region 374, an influence or magnetic-field interference of the magnetic field of the first magnetic region 371 on the digitizer 320 may be reduced compared to a case in which the additional magnetic region 374 is not included, and malfunction of the digitizer 320 may be prevented.

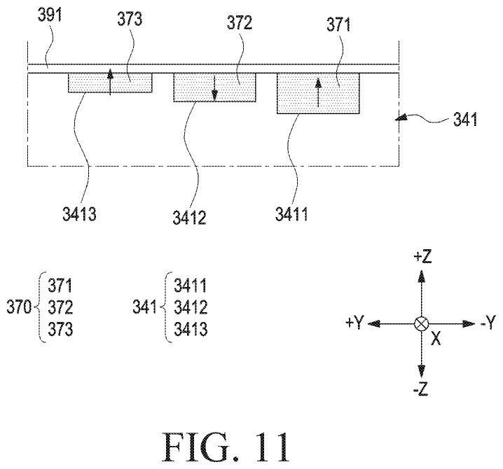

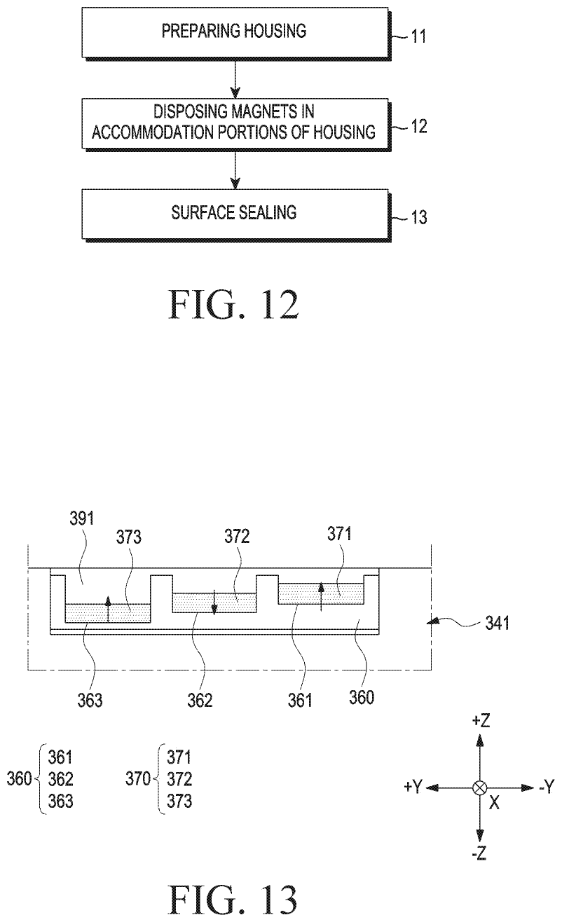

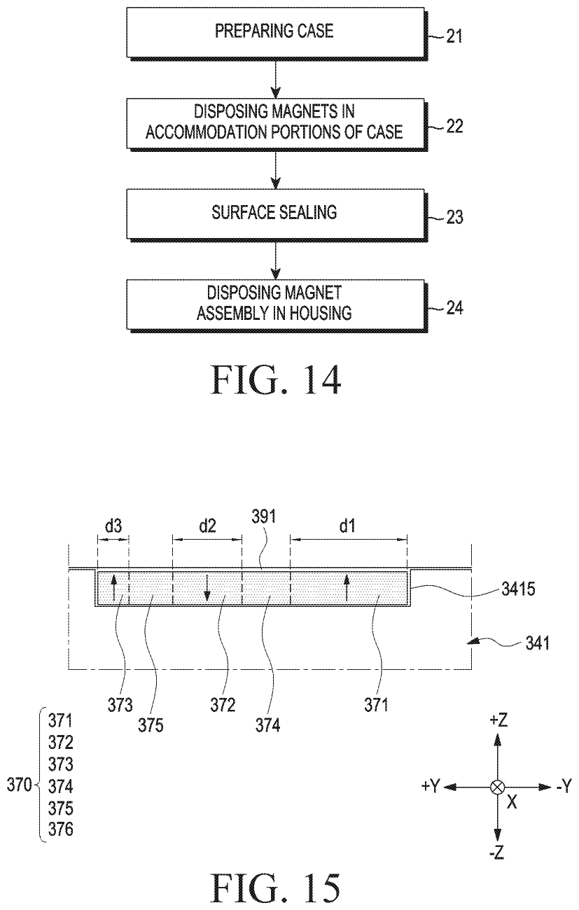

FIG. 11 is a side cross-sectional view illustrating a magnet assembly of an electronic device according to an embodiment of the disclosure. FIG. 12 is a process flowchart illustrating a method of manufacturing the magnet assembly of FIG. 11 according to an embodiment of the disclosure. FIG. 13 is a side cross-sectional view illustrating a magnet assembly of an electronic device according to an embodiment of the disclosure. FIG. 14 is a process flowchart illustrating a method of manufacturing the magnet assembly of FIG. 13 according to an embodiment of the disclosure.

The support structure 341 of FIGS. 11, 13, and 14 may be referred to as the support structure 341 of FIGS. 9A and 9B. The magnet assemblies 370 of FIGS. 11 and 13 may be referred to as the magnet assembly 370 of FIGS. 9A, 9B, 10A, and 10B.

Referring to FIGS. 11 and 12, according to an embodiment, the magnetic regions 371, 372, and 373 of the magnet assembly 370 may be different magnetic members. For example, a first magnetic region 371 (or a first magnetic member), a second magnetic region 372 (or a second magnetic member), and a third magnetic region 373 (or a third magnetic member) may be disposed spaced apart from each other at regular intervals. Although an accommodation portion (e.g., the pen accommodating portion 350 of FIGS. 9A and 9B) and a digital pen 400 (e.g., the digital pen 400 of FIGS. 9A and 9B) are omitted from illustration in FIGS. 11 and 12, the accommodation portion and the digital pen 400 may be disposed above the magnetic regions 371, 372, and 373 (e.g., in a +Z-axis direction), as in the embodiment of FIGS. 9A and 9B. A strength of a magnetic field applied by the magnetic regions 371, 372, and 373 (or the magnetic members) to the digital pen 400 may be set by adjusting sizes of the magnetic regions 371, 372, and 373 as in the embodiment of FIG. 11, or by adjusting distances between the magnetic regions 371, 372, and 373 and the digital pen 400 as in the embodiment of FIG. 12.

Referring to FIG. 11, according to an embodiment, for example, a size of the second magnetic region 372 may be greater than a size of the third magnetic region 373 and smaller than a size of the first magnetic region 371. Referring to FIG. 11, according to an embodiment, a support structure 341 of the housing 340 (for example, the housing 340 of FIGS. 9A and 9B) may include accommodating portions 3411, 3412, and 3413. According to an embodiment, the magnetic regions 371, 372, and 373 of the magnet assembly 370 may be disposed in the accommodating portions 3411, 3412, and 3413.

According to an embodiment, a sealing member 391 may be disposed on one surface of the magnetic regions 371, 372, and 373, for example, a surface facing a +Z-axis direction. The sealing member 391 may be understood as a component included in the electronic device 101 or the magnet assembly 370. For example, the sealing member 391 may cover, together with the magnetic regions 371, 372, and 373, a surface of the support structure 341 positioned between the magnetic regions, for example, a surface facing the +Z-axis direction. For example, the sealing member 391 may protect the magnetic regions 371, 372, and 373 and fix the magnetic regions 371, 372, and 373 to the accommodation portions 3411, 3412, and 3413.

Referring to FIG. 12, a method of manufacturing the magnet assembly 370 may include an operation of preparing (or manufacturing) a housing 340 (or a support structure 341) including accommodation portions 3411, 3412, and 3413 (for example, operation 11 of preparing the housing in FIG. 12). The manufacturing method may include an operation of disposing magnetic regions 371, 372, and 373 (or magnetic members or magnets) in the accommodation portions 3411, 3412, and 3413 of the housing 340 (for example, operation 12 of disposing magnets in the accommodation portions of the housing in FIG. 12). The manufacturing method may include an operation of forming, applying, or disposing a sealing member 391(for example, operation 13 of surface sealing in FIG. 12) on surfaces (e.g., surfaces in the +Z-axis direction) of the accommodation portions 3411, 3412, and 3413 and the magnetic regions 371, 372, and 373.

Referring to FIG. 13, according to an embodiment, the magnet assembly 370 may further include a case 360 (or casing) that supports the magnetic regions 371, 372, and 373. According to an embodiment, the case 360 may include accommodation portions 361, 362, and 363 in which the magnetic regions 371, 372, and 373 (or magnetic members) are disposed. According to an embodiment, depths or heights of the accommodation portions 361, 362, and 363 of the case 360 (e.g., depths or heights in the Z-axis direction) may be different from each other. According to an embodiment, a depth of a second accommodation portion 362 in which the second magnetic region 372 is disposed (e.g., a depth in the Z-axis direction) may be greater than a depth of a first accommodation portion 361 in which the first magnetic region 371 is disposed (e.g., a depth in the Z-axis direction) and less than a depth of a third accommodation portion 363 in which the third magnetic region 373 is disposed (e.g., a depth in the Z-axis direction). In this case, for example, the first magnetic region 371, the second magnetic region 372, and the third magnetic region 373 may have similar or substantially identical sizes. However, in the disclosure, depths and shapes of the accommodation portions 361, 362, and 363 of the case 360 and sizes of the magnetic regions 371, 372, and 373 are not limited thereto and may vary.

According to an embodiment, a sealing member 391 may be disposed on one surface of the magnetic regions 371, 372, and 373 (e.g., a surface in the +Z-axis direction). The sealing member 391 may be understood as a component included in the electronic device 101 or the magnet assembly 370. For example, the sealing member 391 may cover, together with the magnetic regions 371, 372, and 373, a surface (e.g., a surface in the +Z-axis direction) of the support structure 341 positioned between the magnetic regions 371, 372, and 373. For example, the sealing member 391 may protect the magnetic regions 371, 372, and 373 and fix the magnetic regions 371, 372, and 373 to accommodation portions 361, 362, and 363 of the case 360.

Referring to FIG. 14, according to an embodiment, a method of manufacturing the magnet assembly 370 may include an operation of preparing (or manufacturing) a case 360 including accommodation portions 361, 362, and 363 (e.g., operation 21 of preparing a case in FIG. 14). The manufacturing method may include an operation of disposing magnetic regions 371, 372, and 373 (or magnetic members or magnets) in the accommodation portions 361, 362, and 363 of the case 360 (e.g., operation 22 of disposing magnets in the accommodation portions of the case of FIG. 14). The manufacturing method may include an operation of forming, applying, or disposing a sealing member 391 on surfaces (e.g., surfaces in a +Z direction) of the accommodation portions 361, 362, and 363 of the case 360 and/or the magnetic regions 371, 372, and 373 (e.g., operation 23 of surface sealing of FIG. 14). The manufacturing method may include an operation of disposing, in a housing (e.g., the housing 340 of FIGS. 9A and 9B or a support structure 341) of an electronic device (e.g., the electronic device 101 of FIGS. 1 to 8), the magnet assembly 370 including the case 360 and the magnetic regions 371, 372, and 373 (e.g., operation 24 of disposing the magnet assembly in the housing of FIG. 14).

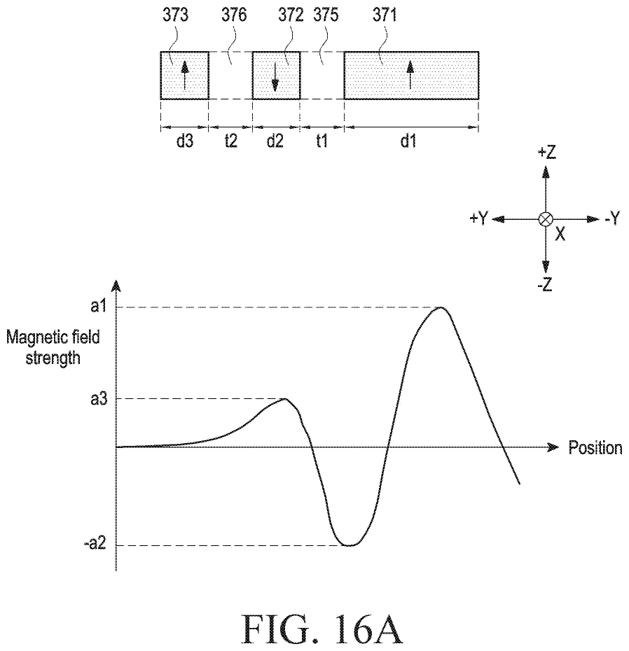

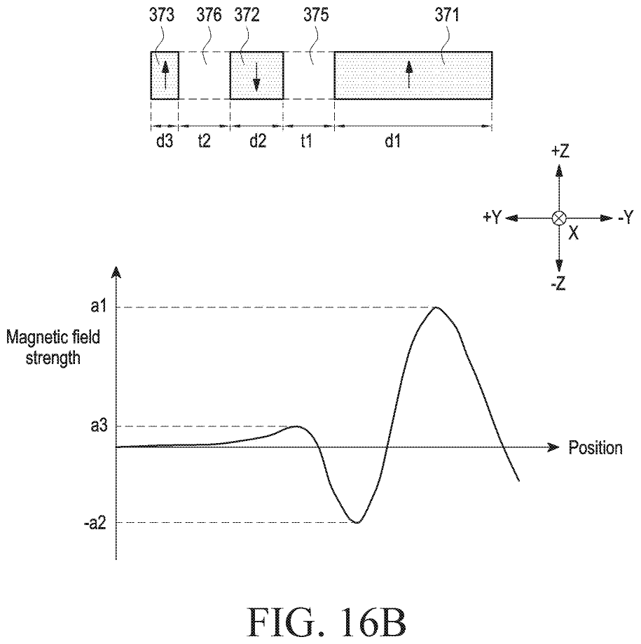

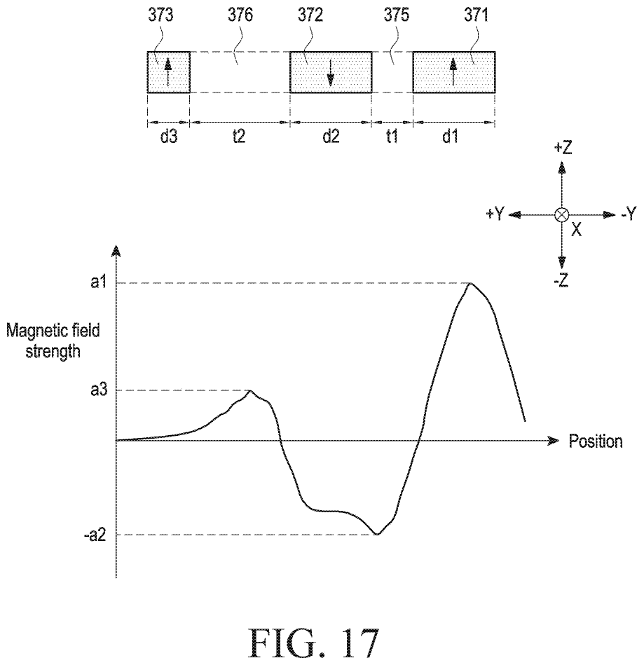

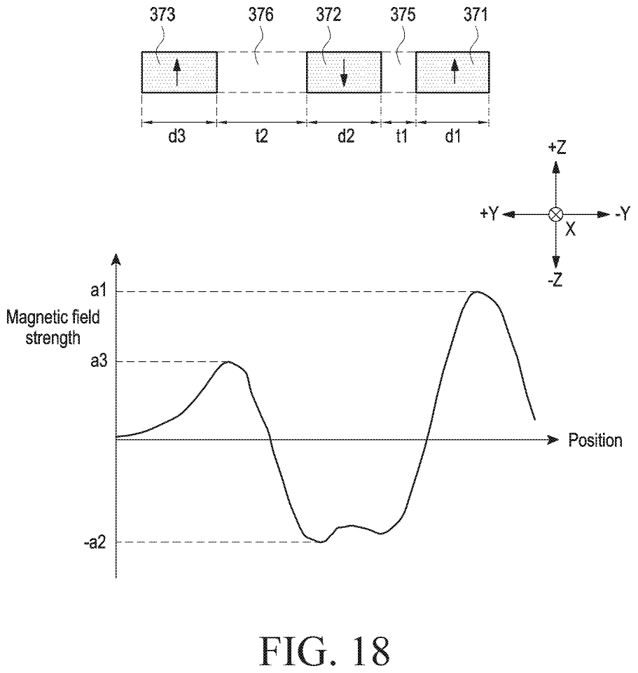

FIG. 15 is a side cross-sectional view illustrating a magnet assembly of an electronic device according to an embodiment of the disclosure. FIGS. 16A and 16B are views illustrating an arrangement of magnetic regions and magnetic field strength of a magnet assembly according to various embodiments of the disclosure. FIG. 17 is a view illustrating an arrangement of magnetic regions and magnetic field strength of a magnet assembly according to an embodiment of the disclosure. FIG. 18 is a view illustrating an arrangement of magnetic regions and magnetic field strength of a magnet assembly according to an embodiment of the disclosure.

The support structure 341 of FIG. 15 may be referred to as the support structure 341 of FIGS. 9A and 9B. It may be referred to as the magnet assembly 370 of FIGS. 9A, 9B, 10A, and 10B. All or part of the configuration of the magnet assembly 370 in the embodiments of FIGS. 15, 16A, 16B, 17, and 18 may be the same as or similar to the configuration of the magnet assembly 370 in the embodiments of FIGS. 9A, 9B, 10A, 10B, and 11 to 14.

Referring to FIG. 15, according to an embodiment, the magnet assembly 370 may include a single magnetic member including magnetic regions 371, 372, and 373. For example, the single magnetic member may have a shape extending in a first axis direction (for example, a Y-axis direction).

According to an embodiment, the magnet assembly 370 may include a plurality of magnetic regions 371, 372, and 373 and non-magnetic regions 384 and 385 disposed between the magnetic regions 371, 372, and 373. For example, the magnetic regions 371, 372, and 373 of the magnet assembly 370 may be formed by multipole magnetizing different regions of a single magnetic member. According to an embodiment, polarities (for example, an N pole or an S pole) of adjacent magnetic regions 371, 372, and 373 among the magnetic regions 371, 372, and 373 of the magnet assembly 370 may be opposite to each other. The non-magnetic regions 384 and 385 may be positioned between the magnetic regions 371, 372, and 373 and may be regions in which a magnetic field is not formed. According to an embodiment, the magnet assembly 370 may include a first non-magnetic region 384 disposed between a first magnetic region 371 and a second magnetic region 372, and a second non-magnetic region 385 disposed between the second magnetic region 372 and a third magnetic region 373. According to an embodiment, a length d2 of the second magnetic region 372 in the first axis direction (for example, the Y-axis direction) may be greater than a length d3 of the third magnetic region 373 in the first axis direction and less than a length d1 of the first magnetic region 371 in the first axis direction.

According to an embodiment, the support structure 341 may include an accommodation portion 3415 configured to accommodate the single magnetic member. According to an embodiment, a sealing member 391 may be disposed on one surface (for example, a surface in a +Z-axis direction) of the support structure 341 and/or the magnetic regions 371, 372, and 373. The sealing member 391 may be understood as a component included in the electronic device 101 or the magnet assembly 370. For example, the sealing member 391 may protect the magnetic regions 371, 372, and 373 and fix the magnetic regions 371, 372, and 373 to the accommodation portion 3415 of the support structure 341.

According to an embodiment, a digital pen 400 (e.g., the digital pen 400 of FIGS. 6, 9A, and 9B) for applying an input signal to a digitizer (e.g., the digitizer 320 of FIGS. 9A and 9B) of an electronic device (e.g., the electronic device 101 of FIGS. 1 to 8) may be magnetized by a surrounding magnet. According to an embodiment of the disclosure, in a process of accommodating the magnetized digital pen 400 in or removing it from a pen accommodating portion 350, the digital pen 400 may be demagnetized by being exposed to a magnetic field (or an attenuated magnetic field) of a magnet assembly 370. According to the demagnetization function of the digital pen 400 by the magnet assembly 370, an input malfunction of the digital pen 400 caused by magnetic-field interference of the magnetized digital pen 400 may be suppressed. Referring to the graphs of FIGS. 16A, 16B, 17, and 18, according to an embodiment, the attenuated magnetic field of the magnet assembly 370 may alternate in a positive (+) direction and a negative (−) direction, and the strength thereof may gradually increase as it moves away from a first through hole (e.g., the first through hole 341a of FIGS. 9A and 9B) (or moves in a −Y direction).

Lengths d1, d2, and d3 of magnetic regions 371, 372, and 373 and spacings t1 and t2 therebetween in the magnet assembly 370 of FIG. 15 may be adjusted to form a magnetic field strength suitable for demagnetization of a digital pen (for example, the digital pen 400 of FIGS. 9A and 9B). In the following description, the lengths d1, d2, and d3 of the magnetic regions 371, 372, and 373 may refer to lengths in a first axis direction (for example, a Y-axis direction), and the spacings t1 and t2 between the magnetic regions 371, 372, and 373 may refer to spacings in the first axis direction (for example, the Y-axis direction). For example, the spacings t1 and t2 between the magnetic regions 371, 372, and 373 may refer to lengths in the first axis direction (for example, the Y-axis direction) of non-magnetic regions 375 and 376.

FIGS. 16A, 16B, 17, and 18 are views illustrating changes in a strength of a magnetic field according to lengths d1, d2, and d3 of magnetic regions 371, 372, and 373 and spacings t1 and t2 therebetween in the magnet assembly 370 of FIG. 15. In FIGS. 16A, 16B, 17, and 18, graphs may represent a magnetic field distribution and a magnetic field strength of the magnet assembly 370. In FIGS. 16A, 16B, 17, and 18, a vertical axis of the graphs may represent a strength of a magnetic field, and a horizontal axis may represent positions of a third magnetic region 373, a second non-magnetic region 376, a second magnetic region 372, a first non-magnetic region 375, and a first magnetic region 371 sequentially arranged from left to right. In FIG. 16A16B, 17, and 18, a1, a2, and a3 of the graphs may respectively represent maximum values of magnetic field strength of the first magnetic region 371, the second magnetic region 372, and the third magnetic region 373, and may be changed according to lengths d1, d2, and d3 and/or spacings t1 and t2 of the magnetic regions 371, 372, and 373.

Referring to FIGS. 16A and 16B, according to an embodiment, a strength of a magnetic field may be adjusted by maintaining spacings t1 and t2 of magnetic regions 371, 372, and 373 constant and changing lengths d1, d2, and d3 of the magnetic regions 371, 372, and 373. For example, a length d2 of a second magnetic region 372 in a first axis direction (for example, a Y-axis direction) may be equal to or greater than a length d3 of a third magnetic region 373 in the first axis direction and less than a length d1 of a first magnetic region 371 in the first axis direction.

Referring to FIG. 17, according to an embodiment, a strength of a magnetic field may be adjusted by changing lengths d1, d2, and d3 of magnetic regions 371, 372, and 373 and spacings t1 and t2 between the magnetic regions 371, 372, and 373. For example, a length d2 of a second magnetic region 372 in a first axis direction (for example, a Y-axis direction) may be equal to or greater than a length d3 of a third magnetic region 373 in the first axis direction (for example, a Y-axis direction) and equal to or less than a length d1 of a first magnetic region 371 in the first axis direction (for example, a Y-axis direction). For example, a first spacing t1 may be less than a second spacing t2.

Referring to FIG. 18, according to an embodiment, a strength of a magnetic field may be adjusted by maintaining lengths d1, d2, and d3 of magnetic regions 371, 372, and 373 constant and changing spacings t1 and t2 between the magnetic regions 371, 372, and 373. For example, a first spacing t1 may be less than a second spacing t2.

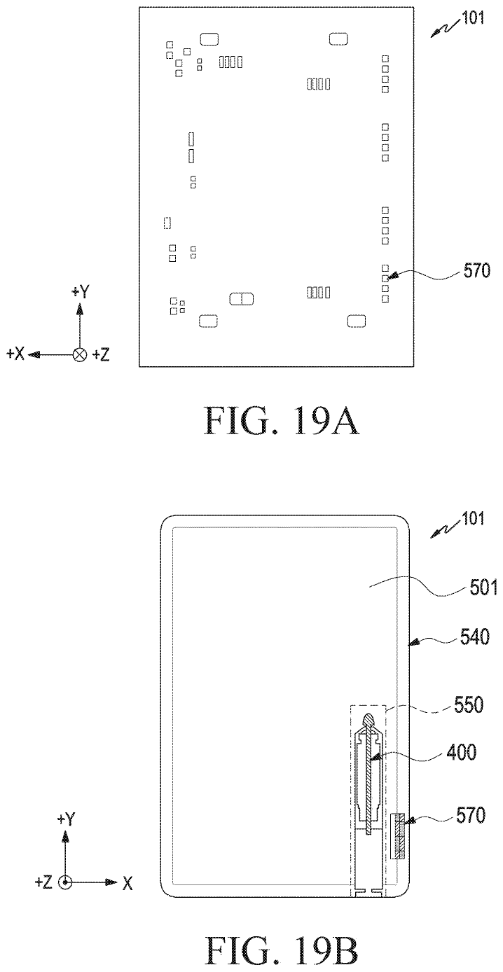

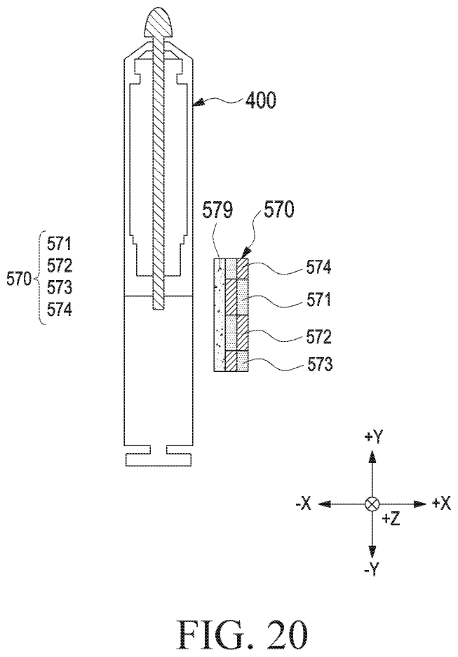

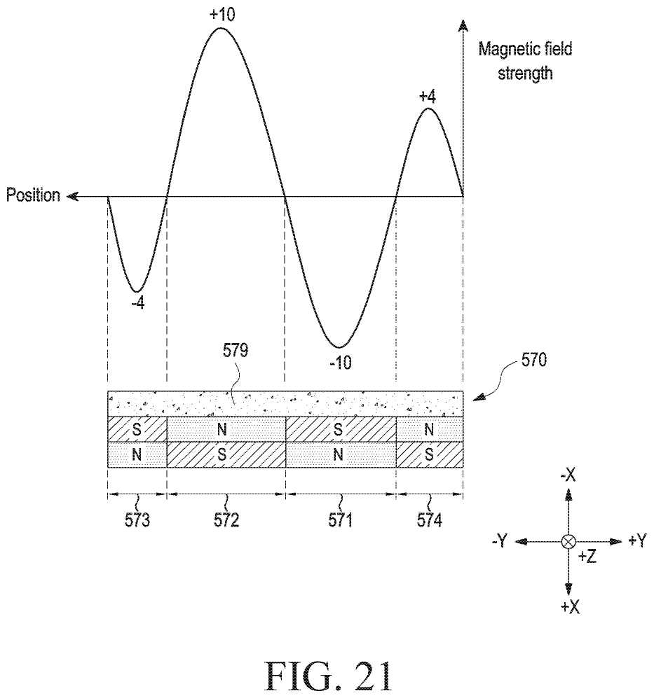

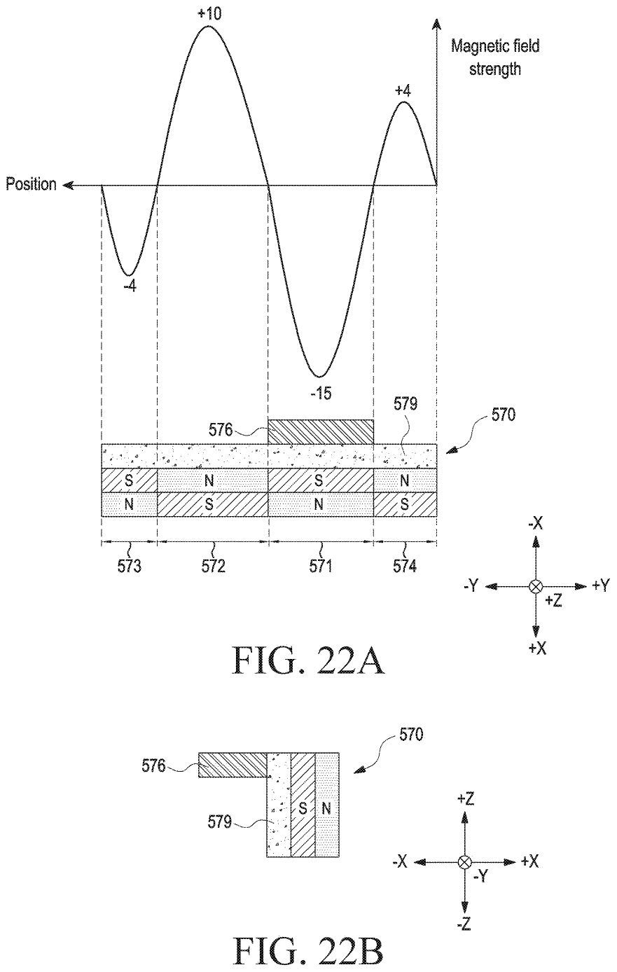

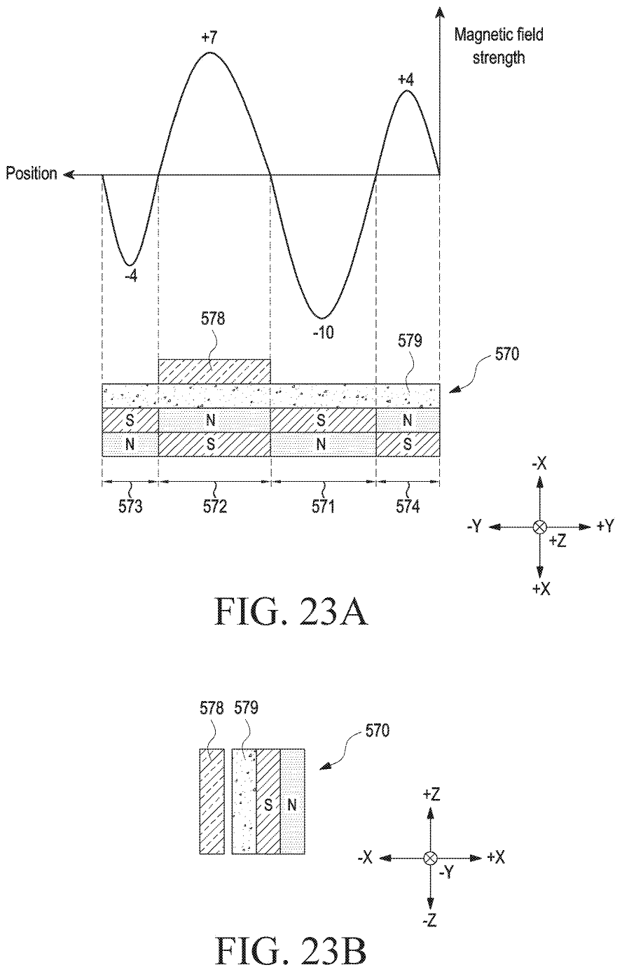

FIG. 19A is a view illustrating a distribution of magnetic members disposed in an electronic device according to an embodiment of the disclosure. FIG. 19B is a plan view illustrating a magnet assembly and a digital pen disposed in an electronic device according to an embodiment of the disclosure. FIG. 20 is a plan view illustrating a magnet assembly and a digital pen according to an embodiment of the disclosure. FIG. 21 is a view illustrating a magnetic field distribution of a magnet assembly according to an embodiment of the disclosure. FIG. 22A is a view illustrating a magnet assembly and a magnetic field distribution according to an embodiment of the disclosure. FIG. 22B is a side cross-sectional view illustrating the magnet assembly of FIG. 22A according to an embodiment of the disclosure. FIG. 23A is a view illustrating a magnet assembly and a magnetic field distribution according to an embodiment of the disclosure. FIG. 23B is a side cross-sectional view illustrating the magnet assembly of FIG. 23A according to an embodiment of the disclosure.

Descriptions of the magnet assembly 370 of the embodiments of FIGS. 8, 9A, 9B, 10A, 10B, 11 to 15, 16A, 16B, 17, and 18 may be applied in the same or similar manner to the magnet assembly 570 of the embodiments of FIGS. 19A, 19B, 20, 21, 22A, 22B, 23A, and 23B. Hereinafter, the magnet assembly 570 according to the embodiments of FIGS. 19A, 19B, 20, 21, 22A, 22B, 23A, and 23B may be described focusing on differences from the magnet assembly 370 of the embodiments of FIGS. 8, 9A, 9B, 10A, 10B, 11 to 15, 16A, 16B, 17, and 18, and common descriptions may be omitted.

FIG. 19A may schematically illustrate positions of conventional magnetic members embedded in an electronic device 101 (for example, a tablet PC). The conventional magnetic members may be embedded, for example, for mounting an accessory such as a cover or an input device to the electronic device 101. According to an embodiment, the magnet assembly 570 of FIGS. 19A, 19B, 20, 21, 22A, 22B, 23A, and 23B may be one of the conventional magnetic members of FIG. 19A.

Referring to FIG. 19B, according to an embodiment, an electronic device 101 may include a housing 540, a display 501, a pen accommodating portion 550, and a magnet assembly 570. According to an embodiment, the display 501 may include a digitizer (for example, the digitizer 320 of FIGS. 6, 9A, and 9B) and a metal sheet (for example, the metal sheet 330 of FIGS. 6, 9A, and 9B). A digital pen 400 (for example, the digital pen 400 of FIGS. 6, 9A, and 9B) may be magnetized by a surrounding magnet during use. According to an embodiment, in a process of accommodating the magnetized digital pen 400 in or removing the magnetized digital pen 400 from the pen accommodating portion 550, the digital pen 400 may be demagnetized by being exposed to a magnetic field (or an attenuated magnetic field) of the magnet assembly 570. According to the demagnetization function of the digital pen 400 by the magnet assembly 570, an input malfunction of the digital pen 400 caused by magnetic field interference of the magnetized digital pen 400 may be suppressed.

According to an embodiment, a digital pen 400 (for example, the digital pen 400 of FIGS. 6, 9A, and 9B) for applying an input signal to a digitizer (for example, the digitizer 320 of FIGS. 9A and 9B) of an electronic device (for example, the electronic device 101 of FIGS. 1 to 8) may be magnetized by a surrounding magnet. According to an embodiment of the disclosure, in a process of accommodating the magnetized digital pen 400 in or removing the magnetized digital pen 400 from a pen accommodating portion 350, the digital pen 400 may be demagnetized by being exposed to a magnetic field (or an attenuated magnetic field) of a magnet assembly 570. According to the demagnetization function of the digital pen 400 by the magnet assembly 570, an input malfunction of the digital pen 400 caused by magnetic field interference of the magnetized digital pen 400 may be suppressed.

Referring to the graphs of FIGS. 16A, 16B, 17, and 18, according to an embodiment, a magnetic field (an attenuated magnetic field) generated by the magnet assembly 570 may alternate in a positive (+) direction and a negative (−) direction. According to an embodiment, the magnetic field (the attenuated magnetic field) generated by the magnet assembly 570 may gradually increase in strength, at least in some sections, as it goes toward an inward direction (+Y direction) of the electronic device 101 or an inward direction (+Y direction) of the pen accommodating portion 350.

Referring to FIGS. 16A, 16B, 17, and 18, according to an embodiment, the magnet assembly 570 may include a third magnetic region 573 (for example, the third magnetic region 373 of FIGS. 9A, 9B, 10A, 10B, 11, 13, and 15), a second magnetic region 572 (for example, the second magnetic region 372 of FIGS. 9A, 9B, 10A, 10B, 11, 13, and 15), a first magnetic region 571 (for example, the first magnetic region 371 of FIGS. 9A, 9B, 10A,10B, 11, 13, and 15), and a fourth magnetic region 574 (for example, the additional magnetic region 374 of FIGS. 9A, 9B, 10A,10B, 11, 13, and 15), which are sequentially arranged toward the inward direction (+Y direction) of the electronic device 101 or the inward direction (+Y direction) of the pen accommodating portion 350.

According to an embodiment, each of the magnetic regions 571, 572, 573, and 574 may include regions having different polarities (for example, an N-pole and an S-pole). According to an embodiment, polarities of adjacent magnetic regions among the magnetic regions 571, 572, 573, and 574 may be opposite to each other. According to an embodiment, a magnetic force (or a strength of a magnetic field) of a second magnetic region 572 may be greater than a magnetic force (or a strength of a magnetic field) of a third magnetic region 573 and equal to or less than a magnetic force (or a strength of a magnetic field) of a first magnetic region 571. According to an embodiment, a magnetic force (or a strength of a magnetic field) of the first magnetic region 571 may be greater than a magnetic force (or a strength of a magnetic field) of a fourth magnetic region 574.

According to an embodiment, a first magnetic region 571 may have a largest magnetic force (or a largest strength of a magnetic field) among magnetic regions 571, 572, 573, and 574, and accordingly, may have a relatively greater influence of magnetic field interference on surrounding electrical/electronic components such as a digitizer (for example, the digitizer 320 of FIGS. 6, 9A, and 9B), compared to a second magnetic region 572 and a third magnetic region 573. For example, the digitizer may be disposed above the magnetic regions 571, 572, and 573 in a +Z-axis direction. A portion of a magnetic field of the first magnetic region 571 may be directed toward a fourth magnetic region 574, thereby suppressing or reducing an influence of the magnetic field of the first magnetic region 571 toward the digitizer (for example, the digitizer 320 of FIGS. 6, 9A, and 9B), and malfunction of the digitizer may be prevented.

According to an embodiment, the magnet assembly 570 may further include a shielding member 579 facing the magnetic regions 571, 572, 573, and 574. For example, the shielding member 579 may reduce an influence of magnetic field interference of the magnet assembly 570 on surrounding electrical/electronic components. For example, the shielding member 579 may be formed of a material suitable for electromagnetic shielding, such as a steel plate cold commercial.

FIGS. 22A and 22B may illustrate examples in which a distribution or a strength of a magnetic field of magnetic regions 571, 572, 573, and 574 is adjusted by further including a guide member 576 and/or an additional shielding member 578 in the magnet assembly 570 of FIG. 21. Referring to the graph of FIG. 21, a secondary attenuated magnetic field may be formed in which a magnetic field strength by a fourth magnetic region 584 is about +4 and a magnetic field strength by a first magnetic region 571 is about −10, such that a positive (+) direction and a negative (−) direction alternate and the strength gradually decreases. Alternatively, referring to the graph of FIG. 21, a secondary attenuated magnetic field may be formed in which a magnetic field strength by a third magnetic region 583 is about −4 and a magnetic field strength by a second magnetic region 572 is about +10, such that a positive (+) direction and a negative (−) direction alternate and the strength gradually decreases.

Referring to FIGS. 22A and 22B, according to an embodiment, the magnet assembly 570 may further include a guide member 576 facing the first magnetic region 571 with the shielding member 579 interposed therebetween. Referring to FIG. 22B, for example, a side surface (for example, a side surface in an X-axis-direction) of the guide member 576 may be disposed to intersect or be perpendicular to a side surface (for example, a side surface in an X-axis-direction) of the shielding member 579. For example, the guide member 576 may include a steel plate cold commercial or a soft magnetic material having high permeability (for example, sendust, ferrite, stainless steel, a nano-crystal material, or an amorphous material).

According to an embodiment, the guide member 576 may be configured to increase or enhance the magnetic field strength of the first magnetic region 571. Referring to the graph of FIG. 22A, a tertiary attenuated magnetic field may be formed in which a magnetic field strength by the third magnetic region 583 is about −4, a magnetic field strength by the second magnetic region 572 is about +10, and a magnetic field strength by the first magnetic region 571 and the guide member 576 is about −15, such that a positive (+) direction and a negative (−) direction alternate and the strength gradually decreases. According to an embodiment, the guide member 576 may increase or enhance the magnetic field of the first magnetic region 571 and form a tertiary attenuated magnetic field instead of the secondary attenuated magnetic field of the magnet assembly 570 of FIG. 21, thereby increasing or enhancing the demagnetization function of the digital pen 400 by the magnet assembly 570.

Referring to FIGS. 23A and 23B, according to an embodiment, the magnet assembly 570 may further include an additional shielding member 578 facing the second magnetic region 571 with a shielding member 579 interposed therebetween. The additional shielding member 578 may shield a portion of a magnetic field of the second magnetic region 571. Referring to FIG. 23B, for example, a side surface (for example, a side surface in an X-axis direction) of the additional shielding member 578 may be disposed in parallel with a side surface (for example, a side surface in an X-axis direction) of the shielding member 579. For example, the additional shielding member 578 may be disposed spaced apart from the shielding member 579. For example, the guide member 576 may include a steel plate cold commercial or a soft magnetic material having high permeability (for example, sendust, ferrite, stainless steel, a nano crystal material, or an amorphous material).

Referring to the graph of FIG. 23A, a tertiary attenuated magnetic field may be formed in which a magnetic field strength by a third magnetic region 583 is about −4, a magnetic field strength by a second magnetic region 572 and an additional shielding member 578 is about +7, and a magnetic field strength by a first magnetic region 571 and a guide member 576 is about −15, such that a positive (+) direction and a negative (−) direction alternate and the strength gradually decreases. The magnetic field strength of the graph of FIG. 23A may represent a strength of a magnetic field applied within the pen accommodating portion 550. According to an embodiment, the additional shielding member 578 may shield a portion of a magnetic field of the second magnetic region 572 and form a tertiary attenuated magnetic field instead of the secondary attenuated magnetic field of the magnet assembly 570 of FIG. 21, thereby enhancing a demagnetization function of the digital pen 400 by the magnet assembly 570.

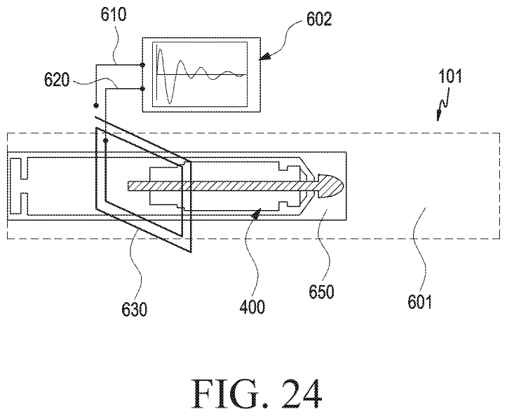

FIG. 24 is a view illustrating a demagnetization device of an electronic device and a digital pen according to an embodiment of the disclosure. All or part of the configuration of the electronic device 101 of FIG. 24 may be referred to as the electronic device 101 of FIGS. 1 to 8.

Referring to FIG. 24, according to an embodiment, the electronic device 101 may include a demagnetization module (or a demagnetizer module) 602 and a pen accommodating portion 650 (for example, the pen accommodating portion 350 of FIGS. 9A and 9B or the pen accommodating portion 550 of FIG. 19B) for accommodating a digital pen (for example, the digital pen 400 of FIGS. 6, 7, 9A, and 9B). According to an embodiment, the demagnetization module 602 may include a coil 630 surrounding the pen accommodating portion 650 and wires 610 and 620 (or a circuit) connected to the coil 630. When a current flows to the coil 630 through the wires 610 and 620 of the demagnetization module 602, a magnetic field may be formed around the coil 630.

According to an embodiment, the digital pen 400 may be magnetized by a surrounding magnet during use. As described later, according to an embodiment of the disclosure, in a use process of accommodating the magnetized digital pen 400 in or removing it from the pen accommodating portion 650, the digital pen 400 may be demagnetized by being exposed to a magnetic field (or an attenuated magnetic field) provided by the demagnetization module 602. According to a demagnetization function of the digital pen 400 by the demagnetization module 602, an input malfunction of the digital pen 400 caused by magnetic field interference of the magnetized digital pen 400 may be suppressed.

According to an embodiment, the demagnetization module 602 may apply, using the coil 630, an attenuated magnetic field (or an attenuated alternating magnetic field) in which magnetic fields having strengths that gradually decrease are alternately applied in a positive (+) direction and a negative (−) direction to the digital pen 400 (or to a coil, for example, ferrite of the coil 401 of FIG. 6).

Specifically, for example, the attenuated magnetic field may demagnetize the digital pen 400 such that residual magnetism of the digital pen 400 becomes zero or close to zero by alternately applying magnetic fields in opposite directions, in a manner of applying a magnetic field that magnetizes the digital pen 400 (or the coil, for example, the ferrite of the coil 401 of FIG. 6) to −9 when the digital pen 400 is magnetized with a strength of +10, applying a magnetic field that magnetizes the digital pen 400 by +8, and applying a magnetic field that magnetizes the digital pen 400 by −7. According to an embodiment, the demagnetization module 602 may generate the attenuated magnetic field by operating in response to detecting an induced current when the digital pen 400 is inserted into or removed from the pen accommodating portion 650. For example, the demagnetization module 602 may operate only temporarily when the digital pen 400 is inserted or removed, and thus, compared to a permanent magnet in which a magnetic field is continuously generated, an influence of magnetic field interference on surrounding electrical/electronic components, such as a digitizer (for example, the digitizer 320 of FIGS. 6, 9A, and 9B), by the attenuated magnetic field may be reduced.

However, the problems to be solved by the disclosure may be variously determined without departing from the spirit and scope of the disclosure. The effects obtainable from the disclosure are not limited to the effects described above, and various effects that can be directly or indirectly recognized through this document may be provided.

According to an embodiment of the disclosure, an electronic device 101 may be provided. The electronic device may include a housing 210, 220, 340, or 540 including a first surface 210A or 340A, a second surface 210B or 340B facing in a direction opposite to the first surface, a side surface 210C or 340C surrounding a space formed between the first surface and the second surface, and a first through hole 341a formed in the side surface, a display 201, 310, or 501 disposed on the first surface of the housing, a digitizer 320 disposed in the housing to face the display, a pen accommodating portion 350 or 550 extending from the first through hole in a first axis direction and disposed between the digitizer and the second surface of the housing, and a magnet assembly 370 including a plurality of magnetic regions 371, 372, and 373 or 571, 572, and 573 arranged in the first axis direction around the pen accommodating portion. Polarities of adjacent magnetic regions may be opposite to each other, and among two adjacent magnetic regions, a magnetic force of a magnetic region disposed closer to the first through hole may be equal to or less than a magnetic force of the other magnetic region.

According to an embodiment, the magnet assembly may be disposed between the digitizer and the second surface of the housing.

According to an embodiment, the magnet assembly may further include an additional magnetic region 375 or 574 disposed to at least partially face a first magnetic region disposed furthest from the first through hole among the plurality of magnetic regions.

According to an embodiment, a magnetic force of the additional magnetic region may be less than a magnetic force of the first magnetic region.

According to an embodiment, the additional magnetic region may be aligned with respect to the first magnetic region in the first axis direction.

According to an embodiment, the magnet assembly may further include a shielding member 579 facing the plurality of magnetic regions.

According to an embodiment, the plurality of magnetic regions of the magnet assembly may include a first magnetic region 371 or 571 disposed furthest from the first through hole, a third magnetic region 373 or 573, and a second magnetic region 372 or 572 disposed between the first magnetic region and the third magnetic region.

According to an embodiment, the magnet assembly may further include a guide member 576 facing the first magnetic region with the shielding member interposed therebetween, and the guide member may be configured to increase a strength of a magnetic field generated by the first magnetic region.

According to an embodiment, the magnet assembly may further include an additional shielding member 578 facing the second magnetic region with the shielding member interposed therebetween, and the additional shielding member may be configured to shield a portion of a magnetic field.

According to an embodiment, a strength of a magnetic field in an area of the pen accommodating portion corresponding to the second magnetic region may be less than a strength of a magnetic field in an area of the pen accommodating portion corresponding to the first magnetic region and greater than a strength of a magnetic field in an area of the pen accommodating portion corresponding to the third magnetic region.

According to an embodiment, the magnet assembly may further include a plurality of magnetic members spaced apart from each other, and the plurality of magnetic members may correspond to the plurality of magnetic regions.

According to an embodiment, at least one of a length of the magnetic members in the first axis direction or a spacing between adjacent magnetic members may be constant.

According to an embodiment, the magnetic members may be arranged such that a distance from the pen accommodating portion decreases as the magnetic members are disposed farther from the first through hole.

According to an embodiment, the magnet assembly may include a magnet extending in the first axis direction, and the plurality of magnetic regions may be formed in different regions of the magnet.

According to an embodiment, the magnet assembly may be configured such that residual magnetization of a digital pen 400 is demagnetized by a magnetic field of the magnet assembly when the digital pen 400 is accommodated in or removed from the pen accommodating portion.

According to an embodiment of the disclosure, an electronic device 101 may be provided. The electronic device may include a housing 210, 220, 340, or 540 including a first surface 210A or 340A and a second surface 210B or 340B facing in a direction opposite to the first surface, a display 201, 310, or 501 disposed on the first surface of the housing, a digitizer 320 disposed in the housing to face the display, and a magnet assembly 370 or 570 disposed between the digitizer and the second surface of the housing. The magnet assembly may include a plurality of magnetic regions 371, 372, and 373 or 571, 572, and 573 arranged in a first axis direction. Polarities of adjacent magnetic regions may be opposite to each other, and among two adjacent magnetic regions, a magnetic force of a magnetic region disposed closer to the first through hole may be equal to or less than a magnetic force of the other magnetic region.

According to an embodiment, the magnet assembly may further include an additional magnetic region 375 or 574 disposed to at least partially face a first magnetic region disposed furthest from the first through hole among the plurality of magnetic regions, and a magnetic force of the additional magnetic region may be less than a magnetic force of the first magnetic region.

According to an embodiment, the magnet assembly may further include a shielding member 579 facing the plurality of magnetic regions; and a guide member 576 facing the first magnetic region with the shielding member interposed therebetween, and the guide member may be configured to increase a strength of a magnetic field generated by the first magnetic region.

According to an embodiment, the magnet assembly may further include a second magnetic region adjacent to the first magnetic region; and an additional shielding member 578 facing the second magnetic region with the shielding member interposed therebetween, and the additional shielding member may be configured to shield a portion of a magnetic field.

According to an embodiment, the housing may further include a side surface 210C or 340C surrounding a space formed between the first surface and the second surface, and a first through hole 341a formed in the side surface.

The electronic device may further include a pen accommodating portion 350 or 550 extending from the first through hole in a first axis direction and disposed between the digitizer and the second surface of the housing.

The magnet assembly of the disclosure described above and the electronic device including the same are not limited by the foregoing embodiments and drawings, and it will be apparent to those of ordinary skill in the art to which the disclosure pertains that various substitutions, modifications, and changes may be made within the technical scope of the disclosure.

Although the disclosure has been illustrated and described with reference to an embodiment, the embodiment should be understood as being for illustrative purposes only and not for limiting the disclosure. It will be apparent to those skilled in the art that various changes in form and details may be made without departing from the overall scope of the disclosure, including the appended claims and equivalents thereof.

The electronic device according to one embodiment of the disclosure may be various types of devices. The electronic devices may include, for example, a portable communication device (e.g., a smartphone), a computer device, a portable multimedia device, a portable medical device, a camera, a wearable device, or a home appliance. The electronic devices according to an embodiment are not limited to those described above.

It should be appreciated that one embodiment of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in an embodiment of the disclosure, the term “module” may include a unit implemented in hardware, software, or firmware, and may interchangeably be used with other terms, for example, “logic,” “logic block,” “portion,” or “circuitry”. A module may be a single integral component, or a minimum unit or portion thereof, adapted to perform one or more functions. For example, according to an embodiment, the module may be implemented in a form of an application-specific integrated circuit (ASIC).

An embodiment of the disclosure may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a compiler or a code executable by an interpreter. The storage medium readable by the machine may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to an embodiment of the disclosure may be included and provided in a computer program product. The computer program products may be traded as commodities between sellers and buyers. The computer program product may be distributed in the form of a machine-readable storage medium (e.g., compact disc read only memory (CD-ROM)), or be distributed (e.g., downloaded or uploaded) online via an application store (e.g., Play Store™), or between two user devices (e.g., smartphones) directly. If distributed online, at least portion of the computer program product may be temporarily generated or at least temporarily stored in the machine-readable storage medium, such as memory of the manufacturer's server, a server of the application store, or a relay server.

According to an embodiment, each component (e.g., a module or a program) of the above-described components may include a single entity or multiple entities. Some of the plurality of entities may be separately disposed in different components. According to an embodiment, one or more of the above-described components may be omitted, or one or more other components may be added. Alternatively or further, a plurality of components (e.g., modules or programs) may be integrated into a single component. In such a case, according to an embodiment, the integrated component may still perform one or more functions of each of the plurality of components in the same or similar manner as they are performed by a corresponding one of the plurality of components before the integration. According to an embodiment, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a housing including a first surface, a second surface facing in a direction opposite to the first surface, a side surface surrounding a space between the first surface and the second surface, and a first through hole in the side surface;
a display disposed on the first surface of the housing;
a digitizer disposed in the housing to face the display;
a pen accommodating portion extending from the first through hole in a first axis direction and disposed between the digitizer and the second surface of the housing; and
a magnet assembly including a plurality of magnetic regions arranged in the first axis direction around the pen accommodating portion,
wherein polarities of adjacent magnetic regions among the plurality of magnetic regions are opposite, and
wherein a magnetic force of one magnetic region of the adjacent magnetic regions disposed closer to the first through hole than another magnetic region of the adjacent magnetic regions is equal to or less than a magnetic force of the other magnetic region.

2. The electronic device of claim 1, wherein the magnet assembly is disposed between the digitizer and the second surface of the housing.

3. The electronic device of claim 1, wherein the magnet assembly further comprises an additional magnetic region that at least partially faces a first magnetic region of the plurality of magnetic regions, the first magnetic region being disposed furthest from the first through hole among the plurality of magnetic regions.

4. The electronic device of claim 3, wherein a magnetic force of the additional magnetic region is less than a magnetic force of the first magnetic region.

5. The electronic device of claim 3, wherein the additional magnetic region is aligned in the first axis direction with respect to the first magnetic region.

6. The electronic device of claims 1, wherein the magnet assembly further includes a shielding member facing the plurality of magnetic regions.

7. The electronic device of claim 6, wherein the plurality of magnetic regions includes:
a first magnetic region disposed furthest from the first through hole;
a third magnetic region; and
a second magnetic region disposed between the first magnetic region and the third magnetic region.

8. The electronic device of claim 7,
wherein the magnet assembly further includes a guide member facing the first magnetic region with the shielding member interposed therebetween, and
wherein the guide member is configured to increase a strength of a magnetic field generated by the first magnetic region.

9. The electronic device of claim 7,
wherein the magnet assembly further includes an additional shielding member facing the second magnetic region with the shielding member interposed between the second magnetic region and the additional shielding member, and
wherein the additional shielding member is configured to shield a portion of a magnetic field.

10. The electronic device of claim 7, wherein a strength of a magnetic field in an area of the pen accommodating portion corresponding to the second magnetic region is less than a strength of a magnetic field in an area of the pen accommodating portion corresponding to the first magnetic region and greater than a strength of a magnetic field in an area of the pen accommodating portion corresponding to the third magnetic region.

11. The electronic device of claim 1,
wherein the magnet assembly further includes a plurality of magnetic members spaced apart from each other, and
wherein the plurality of magnetic members corresponds to the plurality of magnetic regions.

12. The electronic device of claim 11, wherein at least one of (i) a length of each of the magnetic members in the first axis direction is the same or (ii) a spacing between each of adjacent magnetic members of the magnetic members is the same.

13. The electronic device of claim 1,
wherein a magnet of the magnet assembly extends in the first axis direction, and
wherein each of the plurality of magnetic regions is disposed in different regions of the magnet.

14. The electronic device of claims 1, wherein the magnet assembly is configured to demagnetize residual magnetization of a digital pen by a magnetic field of the magnet assembly when the digital pen is accommodated in or removed from the pen accommodating portion.

15. An electronic device, comprising:
a housing including a first surface and a second surface facing in a direction opposite to the first surface;
a display disposed on the first surface of the housing;
a digitizer disposed in the housing to face the display; and
a magnet assembly disposed between the digitizer and the second surface of the housing, the magnet assembly including a plurality of magnetic regions arranged in a first axis direction,
wherein polarities of adjacent magnetic regions among the plurality of magnetic regions are opposite, and
wherein, among two adjacent magnetic regions of the plurality of magnetic regions, a magnetic force of a magnetic region disposed closer to a first through hole of the housing is equal to or less than a magnetic force of another magnetic region of the two adjacent magnetic regions.

16. The electronic device of claim 15, wherein the magnet assembly further includes an additional magnetic region that at least partially faces a first magnetic region of the plurality of magnetic regions, the first magnetic region being disposed furthest from the first through hole among the plurality of magnetic regions.

17. The electronic device of claim 16,
wherein a magnetic force of the additional magnetic region is less than a magnetic force of the first magnetic region, and
wherein the additional magnetic region is aligned in the first axis direction with respect to the first magnetic region.

18. The electronic device of claim 15,
wherein the magnet assembly further includes a shielding member facing the plurality of magnetic regions, and
wherein the plurality of magnetic regions includes:
a first magnetic region disposed furthest from the first through hole;
a third magnetic region; and
a second magnetic region disposed between the first magnetic region and the third magnetic region.

19. The electronic device of claim 18,
wherein the magnet assembly further includes a guide member facing the first magnetic region with the shielding member interposed therebetween, and
wherein the guide member is configured to increase a strength of a magnetic field generated by the first magnetic region.

20. The electronic device of claim 18,
wherein the magnet assembly further includes an additional shielding member facing the second magnetic region with the shielding member interposed between the second magnetic region and the additional shielding member, and
wherein the additional shielding member is configured to shield a portion of a magnetic field.
